(19) United States
(12) Patent Application Publication
(10) Pub. No.: US 2024/0048173 A1
(43) Pub. Date: Feb. 8, 2024

(54) HIGH FREQUENCY MODULE AND COMMUNICATION APPARATUS

(71) Applicant: Murata Manufacturing Co., Ltd., Kyoto (JP)

(72) Inventor: Naoya MATSUMOTO, Kyoto (JP)

(21) Appl. No.: 18/480,579

(22) Filed: Oct. 4, 2023

Related U.S. Application Data
(63) Continuation of application No. PCT/JP2022/014140, filed on Mar. 24, 2022.

(30) Foreign Application Priority Data
Apr. 8, 2021 (JP) 2021-066084

(51) Int. Cl. H04B 1/56; H04B 1/00

(52) U.S. Cl. CPC H04B 1/56; H04B 1/0078

(57) ABSTRACT

A high frequency module includes a mounting substrate, a plurality of components, a resin layer, and a ground electrode. The plurality of components include a first component, a second component, and a third component. The first component is any one of a first filter and a first power amplifier. The second component is any one of a second filter and a second power amplifier. A top surface of the first component and a top surface of the second component are connected to the ground electrode. The first component and the second component are configured to be capable of performing simultaneous transmission. The third component is configured not to perform a simultaneous transmission operation together with the first component and the second component. The third component is disposed between the first component and the second component in plan view from a thickness direction of the mounting substrate.

### CROSS REFERENCE TO RELATED APPLICATION

This is a continuation of International Application No. PCT/JP2022/014140 filed on Mar. 24, 2022 which claims priority from Japanese Patent Application No. 2021-066084 filed on Apr. 8, 2021. The contents of these applications are incorporated herein by reference in their entireties.

### BACKGROUND ART

### Technical Field

The present disclosure relates, in general, to high frequency modules and communication apparatuses, and more particularly, to a high frequency module and a communication apparatus that transmit a first transmission signal and a second transmission signal.

In Patent Document 1, a module that includes a module substrate, a branching filter that is mounted on a mounting surface of the module substrate and includes a transmission filter and a reception filter, and a resin layer that is provided on the mounting surface so as to cover a side surface of the branching filter, upper surfaces of the branching filter and the resin layer forming the same plane, is described. In this module, a metal layer is formed on at least part of the upper surfaces of the branching filter and the resin layer.
Patent Document 1: International Publication No. 2014/013831

### BRIEF SUMMARY

In the module described in Patent Document 1, in the case where, in addition to a first transmission filter (first component) included in the branching filter, a second transmission filter (second component) that is in contact (connection) with a metal film (ground electrode) is further disposed, heat dissipation characteristics of the second transmission filter are improved. However, in the case where the first transmission filter and the second transmission filter perform a simultaneous transmission operation, heat generation at the first transmission filter and the second transmission filter mutually affect each other, and characteristics of the module may be deteriorated.

The present disclosure provides a high frequency module and a communication apparatus capable of suppressing deterioration of characteristics even when two components whose top surfaces are connected to a ground electrode perform a simultaneous transmission operation.

A high frequency module according to an aspect of the present disclosure includes a mounting substrate, a plurality of components, a resin layer, and a ground electrode. The mounting substrate has a first main surface and a second main surface that are opposite to each other. The plurality of components are disposed on the first main surface. The resin layer covers at least part of the plurality of components. The ground electrode covers at least part of the resin layer. The plurality of components include a first component, a second component, and a third component. The first component is any one of a first filter and a first power amplifier that are used for transmission of a first transmission signal. The second component is any one of a second filter and a second power amplifier that are used for transmission of a second transmission signal of a frequency band different from a frequency band of the first transmission signal. A top surface of the first component and a top surface of the second component are connected to the ground electrode. The first component and the second component are configured to be capable of performing simultaneous transmission. The third component is configured not to perform a simultaneous transmission operation together with the first component and the second component. The third component is disposed between the first component and the second component in plan view from a thickness direction of the mounting substrate.

A high frequency module according to an aspect of the present disclosure includes a mounting substrate, a plurality of components, a resin layer, and a ground electrode. The mounting substrate has a first main surface and a second main surface that are opposite to each other. The plurality of components are disposed on the first main surface. The resin layer covers at least part of the plurality of components. The ground electrode covers at least part of the resin layer. The plurality of components include a first component, a second component, and a third component. The first component is any one of a first filter and a first power amplifier that are used for transmission of a first transmission signal. The second component is any one of a second filter and a second power amplifier that are used for transmission of a second transmission signal of a frequency band different from a frequency band of the first transmission signal. The third component is a reception-system component that is used for reception of a reception signal. A top surface of the first component and a top surface of the second component are connected to the ground electrode. The first component and the second component are configured to be capable of performing simultaneous transmission. The reception-system component is disposed between the first component and the second component in plan view from a thickness direction of the mounting substrate.

A high frequency module according to an aspect of the present disclosure includes a mounting substrate, a plurality of components, a resin layer, and a ground electrode. The mounting substrate has a first main surface and a second main surface that are opposite to each other. The plurality of components are disposed on the first main surface. The resin layer covers at least part of the plurality of components. The ground electrode covers at least part of the resin layer. The plurality of components include a first component, a second component, and a third component. The first component is any one of a first filter and a first power amplifier that are used for transmission of a first transmission signal. The second component is any one of a second filter and a second power amplifier that are used for transmission of a second transmission signal of a frequency band different from a frequency band of the first transmission signal. A top surface of the first component and a top surface of the second component are connected to the ground electrode. The third component is configured not to perform a simultaneous transmission operation together with the first component and the second component. The third component is disposed between the first component and the second component in plan view from a thickness direction of the mounting substrate. A combination of the frequency band of the first transmission signal and the frequency band of the second transmission signal is any one of a combination of Band 1 based on 4G standards and n40 based on 5G standards, a combination of Band 3 based on the 4G standards and n40 based on the 5G standards, a combination of Band 1 based on the 4G standards and n41 based on the 5G standards, a combination of Band 3 based on the 4G standards and n41 based on the 5G standards, a combination of Band 39 based on the 4G standards and n41 based on the 5G standards, a combination of Band 66 based on the 4G standards and n41 based on the 5G standards, and a combination of Band 25 based on the 4G standards and n41 based on the 5G standards.

A high frequency module according to an aspect of the present disclosure includes a mounting substrate, a plurality of components, a resin layer, and a ground electrode. The mounting substrate has a first main surface and a second main surface that are opposite to each other. The plurality of components are disposed on the first main surface. The resin layer covers at least part of the plurality of components. The ground electrode covers at least part of the resin layer. The plurality of components include a first component, a second component, and a third component. The first component is any one of a first filter and a first power amplifier that are used for transmission of a first transmission signal. The second component is any one of a second filter and a second power amplifier that are used for transmission of a second transmission signal of a frequency band different from a frequency band of the first transmission signal. The third component is a reception-system component that is used for reception of a reception signal. A top surface of the first component and a top surface of the second component are connected to the ground electrode. The reception-system component is disposed between the first component and the second component in plan view from a thickness direction of the mounting substrate. A combination of the frequency band of the first transmission signal and the frequency band of the second transmission signal is any one of a combination of Band 1 based on 4G standards and n40 based on 5G standards, a combination of Band 3 based on the 4G standards and n40 based on the 5G standards, a combination of Band 1 based on the 4G standards and n41 based on the 5G standards, a combination of Band 3 based on the 4G standards and n41 based on the 5G standards, a combination of Band 39 based on the 4G standards and n41 based on the 5G standards, a combination of Band 66 based on the 4G standards and n41 based on the 5G standards, and a combination of Band 25 based on the 4G standards and n41 based on the 5G standards.

A communication apparatus according to an aspect of the present disclosure includes any one of the high frequency modules described above and a signal processing circuit that processes the first transmission signal and the second transmission signal that pass through the high frequency module.

With a high frequency module and a communication apparatus according to the present disclosure configured as described above, even when two components that are connected to a ground electrode perform a simultaneous transmission operation, deterioration of characteristics can be suppressed.

### BRIEF DESCRIPTION OF THE DRAWINGS

FIG. 1 is a circuit diagram for explaining a configuration of a communication apparatus including a high frequency module according to a first embodiment.

FIG. 2 is a plan view illustrating the arrangement of electronic components on a first main surface of a mounting substrate included in the high frequency module according to the first embodiment.

FIG. 3 is a cross-section view illustrating the high frequency module according to the first embodiment taken along line X1-X1 of FIG. 2.

FIG. 4 is a cross-section view of a high frequency module according to a first modification of the first embodiment.

FIG. 5 is a cross-section view of a high frequency module according to a second modification of the first embodiment.

FIG. 6 is a plan view illustrating the arrangement of electronic components on a first main surface of a mounting substrate included in a high frequency module according to a second embodiment.

FIG. 7 is a cross-section view illustrating the high frequency module according to the second embodiment taken along line X2-X2 of FIG. 6.

FIG. 8 is a plan view illustrating the arrangement of electronic components on a first main surface of a mounting substrate included in a high frequency module according to a third embodiment.

FIG. 9 is a cross-section view illustrating the high frequency module according to the third embodiment taken along line X3-X3 of FIG. 8.

FIG. 10 is a plan view illustrating the arrangement of electronic components on a first main surface of a mounting substrate included in a high frequency module according to a fourth embodiment.

FIG. 11 is a cross-section view illustrating the high frequency module according to the fourth embodiment taken along line X4-X4 of FIG. 10.

FIG. 12 is a cross-section view of a high frequency module according to a fifth embodiment.

### DETAILED DESCRIPTION

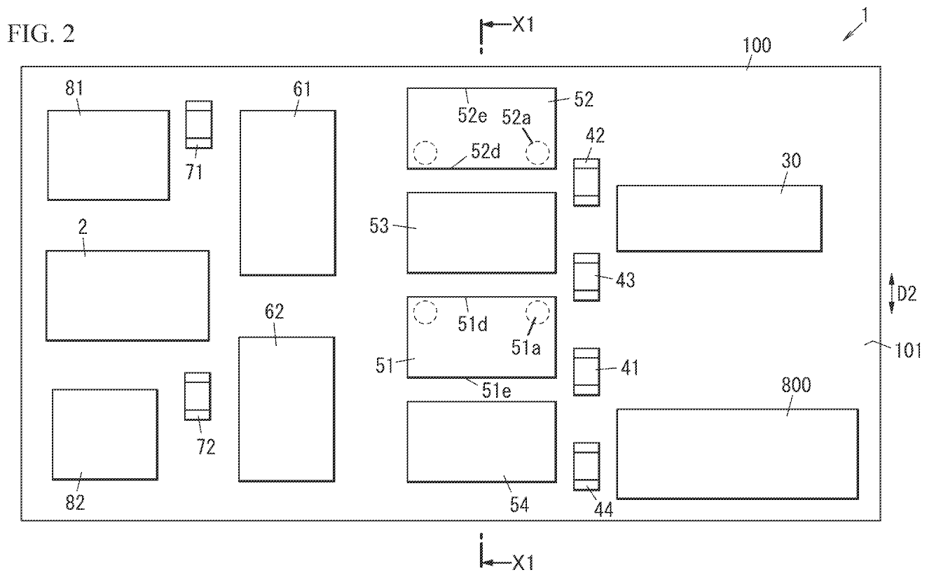

FIGS. 2 to 12 that will be referenced in first to fifth embodiments and the like described below are schematic diagrams, and ratios of the sizes and the thicknesses of component elements in these figures do not necessarily correspond to the actual dimensional ratios.

### First Embodiment

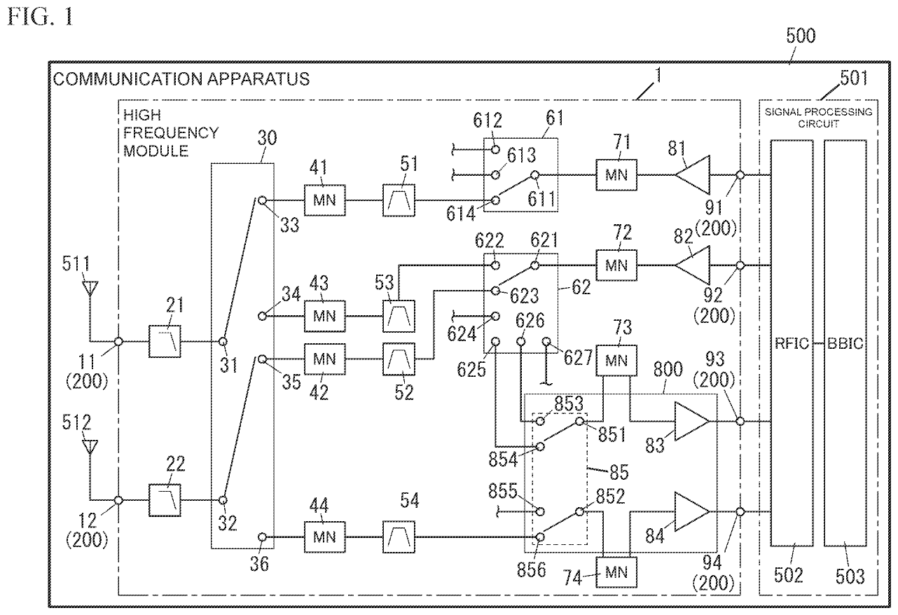

A high frequency module 1 and a communication apparatus 500 according to a first embodiment will be described below with reference to FIGS. 1 to 3.

### (1) Summary

The high frequency module 1 includes, as illustrated in FIG. 1, a plurality of antenna terminals (in this example, a first antenna terminal 11 and a second antenna terminal 12), a first low pass filter 21, a second low pass filter 22, a first switch 30, a first matching circuit 41, a second matching circuit 42, a third matching circuit 43, a fourth matching circuit 44, a first filter 51, a second filter 52, a third filter 53, and a fourth filter 54. The high frequency module 1 further includes a second switch 61, a third switch 62, a fifth matching circuit 71, a sixth matching circuit 72, a seventh matching circuit 73, an eighth matching circuit 74, a first power amplifier 81, a second power amplifier 82, a first low noise amplifier 83, a second low noise amplifier 84, and a fourth switch 85. The high frequency module 1 also includes a plurality of (in the example illustrated in the drawing, two) signal input terminals 91 and 92 and a plurality of (in the example illustrated in the drawing, two) signal output terminals 93 and 94.

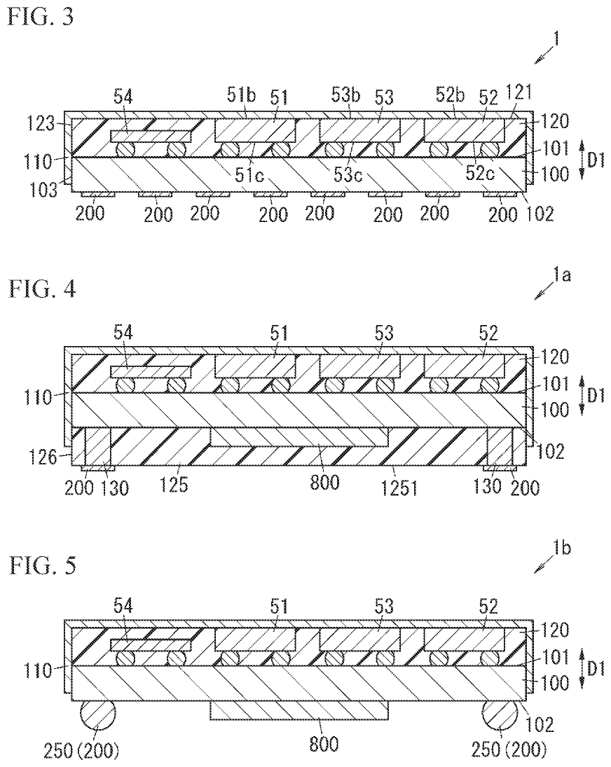

The high frequency module 1 further includes, as illustrated in FIGS. 2 and 3, a mounting substrate 100, a shield layer 110, a resin layer 120, and external connection terminals 200. The mounting substrate 100 has a first main surface 101 and a second main surface 102 that are opposite to each other in a thickness direction D1 of the mounting substrate 100. In the first embodiment, a plurality of components, such as the first filter 51, the second filter 52, the third filter 53, and the fourth filter 54 are disposed on the first main surface 101 of the mounting substrate 100. “A is disposed on the first main surface 101 of the mounting substrate 100” does not necessarily represent a state in which A is mounted directly on the first main surface 101 but may represent a state in which A is disposed in a space that is near the first main surface 101, out of the space that is near the first main surface 101 and a space that is near the second main surface 102, the spaces being isolated from each other by the mounting substrate 100. That is, a state in which A is mounted on the first main surface 101 with other circuit elements or electrodes interposed therebetween.

The high frequency module 1 according to the first embodiment is, for example, used for the communication apparatus 500 supporting multiple modes/multiple bands. The communication apparatus 500 is, for example, a mobile phone (for example, a smartphone). However, the communication apparatus 500 is not necessarily a mobile phone and may be a wearable terminal (for example, a smartwatch). The high frequency module 1 is, for example, a module capable of supporting 4G (fourth generation mobile communications) standards and 5G (fifth generation mobile communications) standards. The 4G standards are, for example, 3GPP (Third Generation Partnership Project) LTE (Long Term Evolution) standards. The 5G standards are, for example, 5G NR (New Radio).

The first antenna terminal 11 is electrically connected to a first antenna 511 (see FIG. 1). The second antenna terminal 12 is electrically connected to a second antenna terminal 512 (see FIG. 1). “A is connected to B” does not necessarily represent a state in which A is in contact with B but also includes a state in which A and B are electrically connected with a conductor electrode, a conductor terminal, a wire, or other circuit components interposed therebetween.

The first switch 30 is configured to be capable of connecting the first filter 51, the second filter 52, the third filter 53, and the fourth filter 54 to each of the first antenna 511 and the second antenna 512. The first switch 30 is configured to be capable of connecting the first filter 51 to the first antenna 511 and connecting the second filter 52 to the second antenna 512 at the same time. That is, the high frequency module 1 is a module capable of supporting carrier aggregation and dual connectivity. Carrier aggregation and dual connectivity represent communications using radio waves of multiple frequency bands at the same time. Hereinafter, signal transmission based on carrier aggregation or dual connectivity may also be referred to as simultaneous transmission. Being capable of performing simultaneous transmission means being capable of transmitting signals by carrier aggregation or dual connectivity.

The high frequency module 1 according to the first embodiment performs communication (transmission) of a signal of a frequency band defined by 4G and communication (transmission) of a signal of a frequency band defined by 5G at the same time. Furthermore, the high frequency module 1 may perform communication of a signal of a frequency band defined by 4G and communication of a signal of a frequency band defined by 4G at the same time. The high frequency module 1 may perform communication of a signal of a frequency band defined by 5G and communication of a signal of a different frequency band defined by 5G at the same time.

In the high frequency module 1 according to the first embodiment, simultaneous transmission is performed using Band 3 (a frequency band from 1710 MHz to 1785 MHz for transmission), which is a frequency band of a mid-band defined by 4G, and n41 (a frequency band from 2496 MHz to 2690 MHz), which is a frequency band of a high band defined by 5G. The band n41 is used for TDD (Time Division Duplex) communications. Band 3 is used for FDD (Frequency Division Duplex).

In the high frequency module 1 according to the first embodiment, a transmission signal of Band 3 (first transmission signal) passes through the first filter 51. In the high frequency module 1 according to the first embodiment, a transmission signal of n41 (second transmission signal) passes through the second filter 52. The third filter 53 is configured not to perform a simultaneous transmission operation together with the first filter 51 and the second filter 52. Combinations of frequency bands used for simultaneous transmission are not limited as long as they are defined by standards. “Not performing a simultaneous transmission operation” represents, at the time when simultaneous transmission using a combination of frequency bands defined by standards is being performed, not performing transmission using a frequency band different from the combination of frequency bands using which simultaneous transmission is being performed and not performing simultaneous communication together with each of the frequency bands using which simultaneous communication is being performed in the high frequency module 1.

The resin layer 120 is disposed near the first main surface 101 of the mounting substrate 100 and covers at least part of an outer peripheral surface (side surface) of a component such as a filter. The resin layer 120 covers outer peripheral surfaces of the first filter 51, the second filter 52, the third filter 53, and the fourth filter 54.

The shield layer 110 is provided on a surface of the resin layer 120 that is far away from the mounting substrate 100 and covers at least part of the resin layer 120. The shield layer 110 is connected to the ground with a ground terminal interposed therebetween. That is, the shield layer 110 may be called a ground electrode.

In the first embodiment, the plurality of components disposed on the first main surface 101 of the mounting substrate 100 include a first component, a second component, and a third component. The first component is a first transmission-system component that is one of the first filter 51 and the first power amplifier 81 used for transmission of a first transmission signal.

The second component is a second transmission-system component that is one of the second filter 52 and the second power amplifier 82 used for transmission of a second transmission signal of a frequency band different from the frequency band of the first transmission signal. In this example, the first transmission-system component is the first filter 51, and the second transmission-system component is the second filter 52.

A top surface of the first filter 51 as the first transmission-system component and the top surface of the second filter 52 as the second transmission-system component are connected to the shield layer 110, which is a ground electrode. Furthermore, as described above, the first filter 51 as the first transmission-system component and the second filter 52 as the second transmission-system component are configured to be capable of performing simultaneous transmission. The third component is configured not to perform a simultaneous transmission operation together with the first transmission-system component and the second transmission-system component. The third component is, for example, the third filter 53. The third filter 53 as the third component is disposed between the first filter 51 as the first transmission-system component and the second filter 52 as the second transmission-system component (see FIG. 2) in plan view from the thickness direction D1 of the mounting substrate 100 (see FIG. 3). The top surface of a component (first transmission-system component, second transmission-system component) is a surface of the component that is far away from the mounting substrate 100, out of two surfaces of the component that are opposite to each other in the thickness direction of the component (the thickness direction D1 of the mounting substrate 100). Furthermore, the bottom surface of a component (first transmission-system component, second transmission-system component) is a surface of the component that is near the mounting substrate 100, out of the two surfaces of the component that are opposite to each other in the thickness direction of the component (the thickness direction D1 of the mounting substrate 100). Furthermore, “a component C is disposed between a component A and a component B in plan view from the thickness direction D1 of the mounting substrate 100” represents a state in which at least one of a plurality of line segments each connecting a point in the component A with a point in the component B passes through the region of the component C in plan view from the thickness direction D1 of the mounting substrate 100. Furthermore, “in plan view from the thickness direction D1 of the mounting substrate 100” represents seeing the mounting substrate 100 and a component disposed at the mounting substrate 100 by orthographical projection onto a plane parallel to a main surface (for example, the first main surface 101) of the mounting substrate 100.

### (2) Configuration

Configurations of the high frequency module 1 and the communication apparatus 500 according to the first embodiment will be described below with reference to FIGS. 1 to 4.

The high frequency module 1 is configured to, for example, amplify a transmission signal (high frequency signal) input from a signal processing circuit 501 (see FIG. 1) and output the amplified signal to a first antenna 511 and a second antenna 512. The high frequency module 1 is configured to, for example, amplify a reception signal (high frequency signal) input from the first antenna 511 and the second antenna 512 and output the amplified signal to the signal processing circuit 501. The signal processing circuit 501 is not a component element of the high frequency module 1 but is a component element of the communication apparatus 500 including the high frequency module 1. The high frequency module 1 is, for example, controlled by the signal processing circuit 501 included in the communication apparatus 500. The communication apparatus 500 includes the high frequency module 1 and the signal processing circuit 501. The communication apparatus 500 further includes the first antenna 511 and the second antenna 512. The communication apparatus 500 further includes a circuit substrate at which the high frequency module 1 is mounted. The circuit substrate is, for example, a printed wiring board. The circuit substrate includes a ground electrode to which a ground potential is applied.

The first antenna 511 is connected to the first antenna terminal 11 of the high frequency module 1. The second antenna 512 is connected to the second antenna terminal 12 of the high frequency module 1. The first antenna 511 and the second antenna 512 include a transmission function for radiating, as a radio wave, a transmission signal output from the high frequency module 1 and a reception function for receiving a reception signal as a radio wave from the outside and outputting the reception signal to the high frequency module 1.

The signal processing circuit 501 processes signals (for example, a reception signal and a transmission signal) passing through the high frequency module 1. The signal processing circuit 501 includes, for example, an RF signal processing circuit 502 and a baseband signal processing circuit 503. The RF signal processing circuit 502 is, for example, an RFIC (Radio Frequency Integrated Circuit) and performs signal processing for a high frequency signal. For example, the RF signal processing circuit 502 performs signal processing such as up-conversion for a high frequency signal (transmission signal) output from the baseband signal processing circuit 503 and outputs the signal-processed high frequency signal. Furthermore, for example, the RF signal processing circuit 502 performs signal processing such as down-conversion for a high frequency signal (reception signal) output from the high frequency module 1 and outputs the signal-processed high frequency signal to the baseband signal processing circuit 503.

The baseband signal processing circuit 503 is, for example, a BBIC (Baseband Integrated Circuit). The baseband signal processing circuit 503 generates an I-phase signal and a Q-phase signal from a baseband signal. Baseband signals include, for example, an audio signal, an image signal, and the like input from the outside. The baseband signal processing circuit 503 performs IQ modulation processing by combining the I-phase signal with the Q-phase signal and outputs a transmission signal. The transmission signal is generated as a modulation signal (IQ signal) obtained by modulating the amplitude of a carrier signal of a predetermined frequency by a period longer than the period of the carrier signal. The reception signal processed at the baseband signal processing circuit 503 is, for example, used as an image signal for image display or an audio signal for conversation. The high frequency module 1 according to the first embodiment transfers a high frequency signal (reception signal) to and from the first and second antennas 511 and 512 and the RF signal processing circuit 502 of the signal processing circuit 501.

The high frequency module 1 includes, as illustrated in FIG. 1, the first antenna terminal 11, the second antenna terminal 12, the first switch 30, the first matching circuit 41, the second matching circuit 42, the third matching circuit 43, the fourth matching circuit 44, the first filter 51, the second filter 52, the third filter 53, and the fourth filter 54. The high frequency module 1 further includes the second switch 61, the third switch 62, the fifth matching circuit 71, the sixth matching circuit 72, the seventh matching circuit 73, the eighth matching circuit 74, the first power amplifier 81, the second power amplifier 82, the first low noise amplifier 83, the second low noise amplifier 84, and the fourth switch 85. Furthermore, the high frequency module 1 includes the plurality of (in the example illustrated in the drawing, two) signal input terminals 91 and 92, the plurality of (in the example illustrated in the drawing, two) signal output terminals 93 and 94, the first low pass filter 21, and the second low pass filter 22.

The first antenna terminal 11 is electrically connected to the first antenna 511. The second antenna terminal 12 is electrically connected to the second antenna 512.

The first low pass filter 21 is disposed between the first antenna terminal 11 and the first switch 30. The second low pass filter 22 is disposed between the second antenna terminal 12 and the first switch 30. In other words, the first low pass filter 21 is connected between the first antenna terminal 11 and the first switch 30. The second low pass filter 22 is connected between the second antenna terminal 12 and the first switch 30. “C is connected between A and B” represents a state in which C is connected to both A and B between A and B. That is, one end of the first low pass filter 21 is connected to the first antenna terminal 11, and the other end of the first low pass filter 21 is connected to the first switch 30. One end of the second low pass filter 22 is connected to the second antenna terminal 12, and the other end of the second low pass filter 22 is connected to the first switch 30.

The first switch 30 is a switch IC composed of a single chip.

The first switch 30 is configured to be capable of connecting the first antenna 511 with the first filter 51 and capable of connecting the second antenna 512 with the second filter 52. The first switch 30 is configured to be capable of connecting the first antenna 511 and the second antenna 512 with the first filter 51 and the second filter 52, respectively, at the same time. That is, the first switch 30 is a switch IC including a switch that is capable of connecting the first antenna 511 with the first filter 51 and capable of connecting the second antenna 512 with the second filter 52.

The first switch 30 is electrically connected to antenna terminals. Specifically, the first switch 30 is electrically connected to the first antenna terminal 11 with the first low pass filter 21 interposed therebetween and to the second antenna terminal 12 with the second low pass filter 22 interposed therebetween. The first switch 30 is electrically connected to the first filter 51, the second filter 52, the third filter 53, and the fourth filter 54.

Specifically, the first switch 30 includes a first terminal 31, a second terminal 32, a third terminal 33, a fourth terminal 34, a fifth terminal 35, and a sixth terminal 36. The first switch 30 selects, as a terminal to which the first terminal 31 is to be connected, one of the third terminal 33, the fourth terminal 34, the fifth terminal 35, and the sixth terminal 36, under the control of the signal processing circuit 501. The first switch 30 selects, as a terminal to which the second terminal 32 is to be connected, one of the third terminal 33, the fourth terminal 34, the fifth terminal 35, and the sixth terminal 36, under the control of the signal processing circuit 501. For example, under the control of the signal processing circuit 501, the first switch 30 selects the third terminal 33, as the terminal to which the first terminal 31 is to be connected, out of the third terminal 33, the fourth terminal 34, the fifth terminal 35, and the sixth terminal 36. Under the control of the signal processing circuit 501, the first switch 30 selects the fifth terminal 35, as the terminal to which the second terminal 32 is to be connected, out of the third terminal 33, the fourth terminal 34, the fifth terminal 35, and the sixth terminal 36.

The first terminal 31 is electrically connected to the first antenna terminal 11. That is, the first terminal 31 is electrically connected to the first antenna 511 with the first low pass filter 21 and the first antenna terminal 11 interposed therebetween. The second terminal 32 is electrically connected to the second antenna terminal 12. That is, the second terminal 32 is electrically connected to the second antenna 512 with the second low pass filter 22 and the second antenna terminal 12 interposed therebetween. The first terminal 31 is not necessarily connected to the first antenna 511 with the first low pass filter 21 interposed therebetween. The first terminal 31 may be connected to the first antenna terminal 11 with a coupler or other components interposed therebetween or may be directly connected to the first antenna terminal 11. Similarly, the second terminal 32 is not necessarily connected to the second antenna 512 with the second low pass filter 22 interposed therebetween. The second terminal 32 may be connected to the second antenna terminal 12 with a coupler or other components interposed therebetween or may be directly connected to the second antenna terminal 12.

The third terminal 33 is electrically connected to the first filter 51. The fourth terminal 34 is electrically connected to the third filter 53. The fifth terminal 35 is electrically connected to the second filter 52. The sixth terminal 36 is electrically connected to the fourth filter 54.

The first matching circuit 41 is, for example, an inductor. More particularly, the first matching circuit 41 is a chip inductor. The first matching circuit 41 is electrically connected to a path between the first switch 30 and the first filter 51 and performs impedance matching between the first switch 30 and the first filter 51.

The second matching circuit 42 is, for example, an inductor. More particularly, the second matching circuit 42 is a chip inductor. The second matching circuit 42 is electrically connected to a path between the first switch 30 and the second filter 52 and performs impedance matching between the first switch 30 and the second filter 52.

The third matching circuit 43 is, for example, an inductor. More particularly, the third matching circuit 43 is a chip inductor. The third matching circuit 43 is electrically connected to a path between the first switch 30 and the third filter 53 and performs impedance matching between the first switch 30 and the third filter 53.

The fourth matching circuit 44 is, for example, an inductor. More particularly, the fourth matching circuit 44 is a chip inductor. The fourth matching circuit 44 is electrically connected to a path between the first switch 30 and the fourth filter 54 and performs impedance matching between the first switch 30 and the fourth filter 54.

The first filter 51 is a transmission filter that allows a transmission signal of Band 3 (first transmission signal) output from the first power amplifier 81 to pass therethrough. The first filter 51 is electrically connected to the first switch 30 with the first matching circuit 41 interposed therebetween. That is, the first filter 51 is connected to the first switch 30 and transmits the first transmission signal. The first filter 51 is, for example, a ladder filter and includes a plurality of (for example, four) series-arm resonators and a plurality of (for example, three) parallel-arm resonators. The first filter 51 is, for example, an acoustic wave filter. In the acoustic wave filter, each of the plurality of series-arm resonators and the plurality of parallel-arm resonators is an acoustic wave resonator. The acoustic wave filter is, for example, a surface acoustic wave filter using surface acoustic waves. In the surface acoustic wave filter, each of the plurality of series-arm resonators and the plurality of parallel-arm resonators is, for example, a SAW (Surface Acoustic Wave) resonator. The first filter 51 is not limited to a SAW filter. The first filter 51 may be a filter different from a SAW filter and may be, for example, a BAW (Bulk Acoustic Wave) filter. A resonator in the BAW filter is, for example, an FBAR (Film Bulk Acoustic Resonator) or an SMR (Solidly Mounted Resonator). The BAW filter includes a substrate. The substrate included in the BAW filter is, for example, a silicon substrate.

The second filter 52 is a filter that allows a transmission signal of n41 (second transmission signal) output from the second power amplifier 82 to pass therethrough. That is, the second filter 52 has a function as a transmission filter. The second filter 52 is electrically connected to the first switch 30 with the second matching circuit 42 interposed therebetween. That is, the second filter 52 is connected to the first switch 30 and transmits the second transmission signal. The second filter 52 is, for example, a ladder filter and includes a plurality of (for example, four) series-arm resonators and a plurality of (for example, three) parallel-arm resonators. The second filter 52 is, for example, an acoustic wave filter. In the acoustic wave filter, each of the plurality of series-arm resonators and the plurality of parallel-arm resonators is an acoustic wave resonator. The acoustic wave filter is, for example, a surface acoustic wave filter using surface acoustic waves. In the surface acoustic wave filter, each of the plurality of series-arm resonators and the plurality of parallel-arm resonators is, for example, a SAW resonator. The second filter 52 is not limited to a SAW filter. The second filter 52 may be a filter different from a SAW filter and may be, for example, a BAW filter.

The third filter 53 is a filter that allows a transmission signal of n40 (third transmission signal) output from the second power amplifier 82 to pass therethrough. That is, the third filter 53 has a function as a transmission filter. The third filter 53 is electrically connected to the first switch 30 with the third matching circuit 43 interposed therebetween. That is, the third filter 53 is connected to the first switch 30 and transmits the third transmission signal. The third filter 53 is, for example, a ladder filter and includes a plurality of (for example, four) series-arm resonators and a plurality of (for example, three) parallel-arm resonators. The third filter 53 is, for example, an acoustic wave filter. In the acoustic wave filter, each of the plurality of series-arm resonators and the plurality of parallel-arm resonators is an acoustic wave resonator. The acoustic wave filter is, for example, a surface acoustic wave filter using surface acoustic waves. In the surface acoustic wave filter, each of the plurality of series-arm resonators and the plurality of parallel-arm resonators is, for example, a SAW resonator. The third filter 53 is not limited to a SAW filter. The third filter 53 may be a filter different from a SAW filter and may be, for example, a BAW filter.

Furthermore, the second filter 52 and the third filter 53 each includes a function as a reception filter. For example, the second filter 52 allows a reception signal of n41 to be input to the first low noise amplifier 83 to pass therethrough. For example, the third filter 53 allows a reception signal of n40 to be input to the first low noise amplifier 83 to pass therethrough.

The fourth filter 54 is, for example, a reception filter that allows a reception signal of Band 3 to be input to the second low noise amplifier 84 to pass therethrough. The frequency band of the reception signal of Band 3 ranges from 1805 MHz to 1880 MHz. The fourth filter 54 is electrically connected to the first switch 30 with the fourth matching circuit 44 interposed therebetween. That is, the fourth filter 54 is connected to the first switch 30 and transmits the reception signal. The fourth filter 54 is, for example, a ladder filter and includes a plurality of (for example, four) series-arm resonators and a plurality of (for example, three) parallel-arm resonators. The fourth filter 54 is, for example, an acoustic wave filter. In the acoustic wave filter, each of the plurality of series-arm resonators and the plurality of parallel-arm resonators is an acoustic wave resonator. The acoustic wave filter is, for example, a surface acoustic wave filter using surface acoustic waves. In the surface acoustic wave filter, each of the plurality of series-arm resonators and the plurality of parallel-arm resonators is, for example, a SAW resonator. The fourth filter 54 is not limited to a SAW filter. The fourth filter 54 may be a filter different from a SAW filter and may be, for example, a BAW filter.

The second switch 61 is composed of a single chip and switches connection between the first power amplifier 81 and the first filter 51. That is, the second switch 61 switches a filter connected to the first power amplifier 81. Specifically, the second switch 61 includes a common terminal 611 and a plurality of (in the example illustrated in the drawing, three) selection terminals 612, 613, and 614. Under the control of the signal processing circuit 501, the second switch 61 selects at least one of the plurality of selection terminals 612, 613, and 614 as a terminal to which the common terminal 611 is to be connected. The common terminal 611 is electrically connected to the first power amplifier 81. The plurality of selection terminals 612, 613, and 614 are connected to the first switch 30. That is, the plurality of selection terminals 612, 613, and 614 are electrically connected to the first antenna terminal 11 or the second antenna terminal 12 with the first switch 30 interposed therebetween. In other words, the plurality of selection terminals 612, 613, and 614 are electrically connected to the first antenna 511 with the first antenna terminal 11 interposed therebetween or to the second antenna 512 with the second antenna terminal 12 interposed therebetween. Specifically, the selection terminal 614 is electrically connected to the first filter 51, and the selection terminal 614 is electrically connected to the first antenna 511 or the second antenna 512 with the first filter 51 interposed therebetween. Connection destinations for the selection terminals 612 and 613 are omitted in the drawing.

The third switch 62 is composed of a single chip and switches connection between the second power amplifier 82 and the second and third filters 52 and 53. That is, the third switch 62 switches a filter connected to the second power amplifier 82. Specifically, the third switch 62 includes a common terminal 621 and a plurality of (in the example illustrated in the drawing, six) selection terminals 622, 623, 624, 625, 626, and 627. Under the control of the signal processing circuit 501, at the time of transmission of a signal, the third switch 62 selects at least one of the plurality of selection terminals 622, 623, and 624 as a terminal to which the common terminal 621 is to be connected. The common terminal 621 is electrically connected to the second power amplifier 82. The plurality of selection terminals 622, 623, and 624 are connected to the first switch 30. That is, the plurality of selection terminals 622, 623, and 624 are electrically connected to the first antenna terminal 11 or the second antenna terminal 12 with the first switch 30 interposed therebetween. In other words, the plurality of selection terminals 622, 623, and 624 are electrically connected to the first antenna 511 with the first antenna terminal 11 interposed therebetween and to the second antenna 512 with the second antenna terminal 12 interposed therebetween. Specifically, the selection terminal 622 is electrically connected to the third filter 53, and the selection terminal 622 is electrically connected to the first antenna 511 or the second antenna 512 with the third filter 53 interposed therebetween. The selection terminal 623 is electrically connected to the second filter 52, and the selection terminal 623 is electrically connected to the first antenna 511 or the second antenna 512 with the second filter 52 interposed therebetween. A connection destination for the selection terminal 624 is omitted in the drawing.

Furthermore, at the time of reception, the third switch 62 connects, under the control of the signal processing circuit 501, one of the selection terminals 622, 623, and 624 with one of the selection terminals 625, 626, and 627. For example, to receive a signal of n41, the third switch 62 connects the selection terminal 623 with the selection terminal 625. To receive a signal of n40, the third switch 62 connects the selection terminal 622 with the selection terminal 626. A connection destination for the selection terminal 627 is omitted in the drawing.

The fifth matching circuit 71 is, for example, an inductor. More particularly, the fifth matching circuit 71 is a chip inductor. The fifth matching circuit 71 is electrically connected to a path between the second switch 61 and the first power amplifier 81 and performs impedance matching between the second switch 61 and the first power amplifier 81.

The sixth matching circuit 72 is, for example, an inductor. More particularly, the sixth matching circuit 72 is a chip inductor. The sixth matching circuit 72 is electrically connected to a path between the third switch 62 and the second power amplifier 82 and performs impedance matching between the third switch 62 and the second power amplifier 82.

The seventh matching circuit 73 is, for example, an inductor. More particularly, the seventh matching circuit 73 is a chip inductor. The seventh matching circuit 73 is electrically connected to a path between the fourth switch 85 and the first low noise amplifier 83 and performs impedance matching between the fourth switch 85 and the first low noise amplifier 83.

The eighth matching circuit 74 is, for example, an inductor. More particularly, the eighth matching circuit 74 is a chip inductor. The eighth matching circuit 74 is electrically connected to a path between the fourth switch 85 and the second low noise amplifier 84 and performs impedance matching between the fourth switch 85 and the second low noise amplifier 84.

The first power amplifier 81 is an amplifier that amplifies a transmission signal of Band 3 (first transmission signal) output from the RF signal processing circuit 502 of the signal processing circuit 501. An input terminal of the first power amplifier 81 is electrically connected to the signal input terminal 91. An output terminal of the first power amplifier 81 is electrically connected to the fifth matching circuit 71. That is, the first power amplifier 81 is electrically connected to the first filter 51 with the fifth matching circuit 71 interposed therebetween. In other words, the first power amplifier 81 is electrically connected to the first switch 30 with the first filter 51 interposed therebetween.

The second power amplifier 82 is an amplifier that amplifies a transmission signal of n41 (second transmission signal) or a transmission signal of n40 output from the RF signal processing circuit 502 of the signal processing circuit 501. An input terminal of the second power amplifier 82 is electrically connected to the signal input terminal 92. An output terminal of the second power amplifier 82 is electrically connected to the sixth matching circuit 72. That is, the second power amplifier 82 is electrically connected to the second filter 52 with the sixth matching circuit 72 interposed therebetween. In other words, the second power amplifier 82 is electrically connected to the first switch 30 with the second filter 52 interposed therebetween.

The first low noise amplifier 83 is an amplifier that amplifies with low noise a reception signal that has passed through the second filter 52 or the third filter 53. An input terminal of the first low noise amplifier 83 is electrically connected to the seventh matching circuit 73, and an output terminal of the first low noise amplifier 83 is electrically connected to the signal output terminal 93. That is, the first low noise amplifier 83 is electrically connected to the second filter 52 or the third filter 53 with the seventh matching circuit 73 interposed therebetween. In other words, the first low noise amplifier 83 is electrically connected to the first switch 30 with the second filter 52 or the third filter 53 interposed therebetween.

The second low noise amplifier 84 is an amplifier that amplifies with low noise a reception signal that has passed through the fourth filter 54. An input terminal of the second low noise amplifier 84 is electrically connected to the eighth matching circuit 74, and an output terminal of the second low noise amplifier 84 is electrically connected to the signal output terminal 94. That is, the second low noise amplifier 84 is electrically connected to the fourth filter 54 with the eighth matching circuit 74 interposed therebetween. In other words, the second low noise amplifier 84 is electrically connected to the first switch 30 with the fourth filter 54 interposed therebetween.

The fourth switch 85 is configured to be capable of connecting the seventh matching circuit 73 with the third switch 62 and capable of connecting the eighth matching circuit 74 with the fourth filter 54. Specifically, the fourth switch 85 includes a first terminal 851, a second terminal 852, a third terminal 853, a fourth terminal 854, a fifth terminal 855, and a sixth terminal 856.

The first terminal 851 is electrically connected to the seventh matching circuit 73. That is, the first terminal 851 is electrically connected to the first low noise amplifier 83 with the seventh matching circuit 73 interposed therebetween. The second terminal 852 is electrically connected to the eighth matching circuit 74. That is, the second terminal 852 is electrically connected to the second low noise amplifier 84 with the eighth matching circuit 74 interposed therebetween.

The third terminal 853 is electrically connected to the selection terminal 626 of the third switch 62. The fourth terminal 854 is electrically connected to the selection terminal 625 of the third switch 62. The sixth terminal 856 is electrically connected to the fourth filter 54. A connection destination for the fifth terminal 855 is omitted in the drawing.

For example, to receive a signal based on the 5G standards, the fourth switch 85 selects one of the third terminal 853 and the fourth terminal 854 as a terminal to which the first terminal 851 is to be connected, under the control of the signal processing circuit 501. That is, to receive a signal based on the 5G standards, the fourth switch 85 switches a filter connected to the first low noise amplifier 83. For example, to receive a signal of n40, the fourth switch 85 selects the third terminal 853 as a terminal to which the first terminal 851 is to be connected, under the control of the signal processing circuit 501. To receive a signal of n41, the fourth switch 85 selects the fourth terminal 854 as a terminal to which the first terminal 851 is to be connected, under the control of the signal processing circuit 501.

Furthermore, for example, to receive a signal based on the 4G standards, the fourth switch 85 selects one of the fifth terminal 855 and the sixth terminal 856 as a terminal to which the second terminal 852 is to be connected, under the control of the signal processing circuit 501. That is, to receive a signal based on the 4G standards, the fourth switch 85 switches a filter connected to the second low noise amplifier 84. For example, to receive a signal of Band 3, the fourth switch 85 selects the sixth terminal 856 as a terminal to which the second terminal 852 is to be connected, under the control of the signal processing circuit 501.

In the first embodiment, the first low noise amplifier 83, the second low noise amplifier 84, and the fourth switch 85 are integrated into a single chip to form a switch IC 800 (see FIG. 2).

The plurality of (in the example illustrated in the drawing, two) signal input terminals 91 and 92 and the plurality of (in the example illustrated in the drawing, two) signal output terminals 93 and 94 are connected to the RF signal processing circuit 502. That is, the first power amplifier 81 is electrically connected to the RF signal processing circuit 502 with the signal input terminal 91 interposed therebetween. The second power amplifier 82 is electrically connected to the RF signal processing circuit 502 with the signal input terminal 92 interposed therebetween. The first low noise amplifier 83 is electrically connected to the RF signal processing circuit 502 with the signal output terminal 93 interposed therebetween. The second low noise amplifier 84 is electrically connected to the RF signal processing circuit 502 with the signal output terminal 94 interposed therebetween.

The high frequency module 1 further includes a controller 2 (see FIG. 2). The controller 2 is, for example, a single-chip IC including a substrate and a circuit part. The substrate has a first surface and a second surface that are opposite to each other. The substrate is, for example, a silicon substrate. The circuit part includes a control circuit that controls the first power amplifier 81 and the second power amplifier 82 in accordance with control signals from the signal processing circuit 501. The controller 2 is, for example, flip-chip mounted on the first main surface 101 of the mounting substrate 100 in such a manner that the first surface of the substrate is near the first main surface 101 of the mounting substrate 100.

As illustrated in FIGS. 2 and 3, the high frequency module 1 further includes the mounting substrate 100, the shield layer 110, the resin layer 120, and the external connection terminals 200. The mounting substrate 100 has the first main surface 101 and the second main surface 102 that are opposite to each other in the thickness direction D1 of the mounting substrate 100.

The mounting substrate 100 is, for example, a printed wiring board, an LTCC (Low Temperature Co-fired Ceramics) substrate, an HTCC (High Temperature Co-fired Ceramics) substrate, or a resin multilayer substrate. In this example, the mounting substrate 100 is a multilayer substrate including a plurality of dielectric layers and a plurality of conductive layers and is a ceramic substrate. The plurality of dielectric layers and the plurality of conductive layers are laminated in the thickness direction D1 of the mounting substrate 100. The plurality of conductive layers are formed in predetermined patterns set for the individual layers. Each of the plurality of conductive layers includes one or a plurality of conductor units on a plane that is orthogonal to the thickness direction D1 of the mounting substrate 100. A material of each of the conductive layers is, for example, copper. The plurality of conductive layers include a ground layer. In the high frequency module 1, one or more ground terminals included in the plurality of external connection terminals 200 (see FIG. 3) and the ground layer are electrically connected with a via conductor, a pad, or the like, which is included in the mounting substrate 100, interposed therebetween.

The mounting substrate 100 is not limited to a printed wiring board or an LTCC substrate and may be a wiring structure body. The wiring structure body is, for example, a multilayer structure body. The multilayer structure body includes at least one insulating layer and at least one conductive layer. The insulating layer is formed in a predetermined pattern. In the case where a plurality of insulating layers are provided, the plurality of insulating layers are formed in predetermined patterns set for the individual layers. The conductive layer is formed in a predetermined pattern different from the predetermined pattern of the insulating layer. In the case where a plurality of conductive layers are provided, the plurality of conductive layers are formed in predetermined patterns set for the individual layers. The conductive layer may include one or a plurality of redistribution parts. In the wiring structure body, a first surface, out of two surfaces that are opposite to each other in the thickness direction of the multilayer structure body, corresponds to the first main surface 101 of the mounting substrate 100, and a second surface out of the two surfaces corresponds to the second main surface 102 of the mounting substrate 100. The wiring structure body may be, for example, an interposer. The interposer may be an interposer including a silicon substrate or may be a substrate including multiple layers.

The first main surface 101 and the second main surface 102 of the mounting substrate 100 are away from each other in the thickness direction D1 of the mounting substrate 100 and intersect in the thickness direction D1 of the mounting substrate 100. For example, the first main surface 101 of the mounting substrate 100 is orthogonal to the thickness direction D1 of the mounting substrate 100. However, for example, a side surface of the conductor unit may be included as a surface that is not orthogonal to the thickness direction D1. Furthermore, for example, the second main surface 102 of the mounting substrate 100 is orthogonal to the thickness direction D1 of the mounting substrate 100. However, for example, a side surface of the conductor unit may be included as a surface that is not orthogonal to the thickness direction D1. Furthermore, fine roughnesses, recesses, or protrusions may be formed in the first main surface 101 and the second main surface 102 of the mounting substrate 100. The mounting substrate 100 has a rectangular shape in plan view from the thickness direction D1 of the mounting substrate 100. However, the mounting substrate 100 does not necessarily have a rectangular shape and may have, for example, a square shape.

The high frequency module 1 includes a plurality of components. The plurality of components include the first low pass filter 21, the second low pass filter 22, the first switch 30, the first matching circuit 41, the second matching circuit 42, the third matching circuit 43, the fourth matching circuit 44, the first filter 51, the second filter 52, the third filter 53, the fourth filter 54, the second switch 61, the third switch 62, the fifth matching circuit 71, the sixth matching circuit 72, the seventh matching circuit 73, the eighth matching circuit 74, the first power amplifier 81, the second power amplifier 82, and the switch IC 800. The outer peripheral shape of each of the plurality of components in plan view from the thickness direction D1 of the mounting substrate 100 is a quadrilateral shape (rectangular shape).

Each of the plurality of components of the high frequency module 1 is mounted on the first main surface 101 or the second main surface 102 of the mounting substrate 100. In the first embodiment, each of the plurality of electronic components of the high frequency module 1 is disposed on the first main surface 101.

The plurality of external connection terminals 200 are each formed in a rectangular column shape and are disposed on the second main surface 102. More particularly, a material of each of the plurality of external connection terminals 200 is, for example, metal (for example, copper or copper alloy).

The plurality of external connection terminals 200 include the first antenna terminal 11, the second antenna terminal 12, the one or more ground terminals, the signal input terminals 91 and 92, and the signal output terminals 93 and 94. The one or more ground terminals are connected to the ground layer of the mounting substrate 100, as described above. The ground layer is a circuit ground of the high frequency module 1, and the plurality of electronic components of the high frequency module 1 include an electronic component connected to the ground layer.

A part of the resin layer 120 that is near the first main surface 101 of the mounting substrate 100 covers at least part of the plurality of electronic components disposed on the first main surface 101 of the mounting substrate 100. Thus, the resin layer 120 seals the plurality of electronic components disposed on the first main surface 101 of the mounting substrate 100. The resin layer 120 includes resin (for example, epoxy resin). The resin layer 120 may include a filler as well as resin.

The shield layer 110 covers at least part of the resin layer 120 (see FIG. 2). The shield layer 110 has conductive characteristics. The shield layer 110 has a multilayer structure in which a plurality of metal layers are laminated. However, the shield layer 110 does not necessarily have a multilayer structure and may be composed of a single metal layer. The metal layer includes one or a plurality of types of metal. The shield layer 110 covers a main surface 121 of the resin layer 120 that is far away from the mounting substrate 100, an outer peripheral surface 123 of the resin layer 120, and at least part of an outer peripheral surface 103 of the mounting substrate 100. The shield layer 110 further covers the first filter 51, which is the first transmission-system component, the second filter 52, which is the second transmission-system component, and the third filter 53, which is the third component. The shield layer 110 is electrically connected to the ground terminal included in the mounting substrate 100. Thus, the shield layer 110 has the same potential as the potential of the ground layer. That is, the shield layer 110 can also serve as a ground electrode.

Next, the arrangement relationship between a plurality of components, in particular, the arrangement relationship between the first filter 51, the second filter 52, and the third filter 53, will be described.

The first filter 51 includes an input terminal 51a to which the first transmission signal is input, and the second filter 52 includes an input terminal 52a to which the second transmission signal is input (see FIG. 2).

The first filter 51 has two surfaces (top surface 51b and bottom surface 51c) that are opposite to each other in the thickness direction of the first filter (the thickness direction D1 of the mounting substrate 100) (see FIG. 3). The second filter 52 has two surfaces (top surface 52b and bottom surface 52c) that are opposite to each other in the thickness direction of the second filter (see FIG. 3). The third filter 53 has two surfaces (top surface 53b and bottom surface 53c) that are opposite to each other in the thickness direction of the third filter (see FIG. 3).

The top surface 51b of the first filter 51 and the top surface 52b of the second filter 52 are connected to the shield layer 110 (see FIG. 3). Furthermore, in the first embodiment, the top surface 53b of the third filter 53 is connected to the shield layer 110 (see FIG. 3).

The third filter 53 is disposed between the first filter 51 and the second filter 52 in plan view from the thickness direction D1 of the mounting substrate 100. In the first embodiment, the first filter 51, the second filter 52, and the third filter 53 are arranged in such a manner that the third filter 53 is disposed between the first filter 51 and the second filter 52 along a direction D2 that is orthogonal to (intersects) the thickness direction D1.

More particularly, the first filter 51, the second filter 52, and the third filter 53 are arranged along a short side of the first filter 51 in plan view from the thickness direction D1 of the mounting substrate 100. Furthermore, the first filter 51, the second filter 52, and the third filter 53 are arranged along a short side of the second filter 52 in plan view from the thickness direction D1 of the mounting substrate 100. Moreover, the first filter 51, the second filter 52, and the third filter 53 are arranged along a short side of the third filter 53 in plan view from the thickness direction D1 of the mounting substrate 100. That is, in the first embodiment, the first filter 51, the second filter 52, and the third filter 53 are arranged along the short sides of the first filter 51, the second filter 52, and the third filter 53. In other words, the third filter 53 (third component) is arranged in such a manner that a long side of the third filter 53 intersects a direction (for example, the direction D2) along the short side of the first filter 51 (first component). Furthermore, the third filter 53 (third component) is arranged in such a manner that the long side of the third filter 53 intersects a direction (for example, the direction D2) along the short side of the second filter 52 (first component).

The input terminal 51a of the first filter 51 (see FIG. 2) is arranged near a side 51d that is closer to the third filter 53, out of two sides 51d and 51e of the first filter 51 that intersect the direction (direction D2) along which the first filter 51, the second filter 52, and the third filter 53 are arranged.

The input terminal 52a of the second filter 52 is arranged near a side 52d that is closer to the third filter 53, out of two sides 52d and 52e of the second filter 52 that intersect the direction (direction D2) along which the first filter 51, the second filter 52, and the third filter 53 are arranged.

### (3) Effects

As described above, the high frequency module 1 according to the first embodiment includes the mounting substrate 100, the plurality of components, the resin layer 120, and the ground electrode (for example, the shield layer 110). The mounting substrate 100 has the first main surface 101 and the second main surface 102 that are opposite to each other. The plurality of components are disposed on the first main surface 101. The resin layer 120 covers at least part of the plurality of components. The ground electrode covers at least part of the resin layer 120. The plurality of components include the first component, the second component, and the third component. The first component is, for example, a first transmission-system component, which is the first filter 51 used for transmission of a first transmission signal. The second component is, for example, a second transmission-system component, which is the second filter 52 used for transmission of a second transmission signal of a frequency band different from the frequency band of the first transmission signal. The top surface (for example, the top surface 51b) of the first transmission-system component and the top surface (for example, the top surface 52b) of the second transmission-system component are connected to the ground electrode. The first transmission-system component and the second transmission-system component are configured to be capable of performing simultaneous transmission. The third component is configured not to perform a simultaneous transmission operation together with the first transmission-system component and the second transmission-system component. The third component is disposed between the first transmission-system component and the second transmission-system component in plan view from the thickness direction D1 of the mounting substrate 100.

With this arrangement, the third component, which does not perform a simultaneous transmission operation together with the first transmission-system component and the second transmission-system component, is disposed between the first transmission-system component and the second transmission-system component in plan view from the thickness direction D1 of the mounting substrate 100. That is, even when the first transmission-system component and the second transmission-system component perform a simultaneous transmission operation, the third component does not perform an operation. Thus, compared to the case where the first transmission-system component and the second transmission-system component are adjacent to each other and thermal interference thus occurs, mutual influence of heat generation at the first transmission-system component and the second transmission-system component is small. This is because part of heat generated at the first transmission-system component and moving toward the second transmission-system component and part of heat generated at the second transmission-system component and moving toward the first transmission-system component flow into the third component and the inflow of the heat into the third component contributes to reducing thermal interference between the first transmission-system component and the second transmission-system component. Consequently, in the high frequency module 1 according to the first embodiment, even when the first transmission-system component and the second transmission-system component that are connected to the shield layer 110 (ground electrode) perform a simultaneous transmission operation, deterioration of characteristics can be suppressed. “A and B are adjacent to each other” represents a state in which no component is present between A and B.

### (4) Modifications

Modifications of the first embodiment will be described below.

### (4.1) First Modification

In the first embodiment, each of the plurality of electronic components included in the high frequency module 1 is mounted on the first main surface 101 of the mounting substrate 100. However, the plurality of electronic components are not necessarily arranged as described above.

At least one of the plurality of electronic components may be provided on the second main surface 102 of the mounting substrate 100. A high frequency module 1a according to a first modification will be described below with reference to FIG. 4. In the first modification, component elements similar to component elements of the high frequency module 1 according to the first embodiment will be denoted by the same signs as those in the first embodiment, and description of the similar component elements will be omitted in an appropriate manner.

Similarly to the high frequency module 1 according to the first embodiment, the high frequency module 1a includes a plurality of components. The plurality of components include the first low pass filter 21, the second low pass filter 22, the first switch 30, the first matching circuit 41, the second matching circuit 42, the third matching circuit 43, the fourth matching circuit 44, the first filter 51, the second filter 52, the third filter 53, the fourth filter 54, the second switch 61, the third switch 62, the fifth matching circuit 71, the sixth matching circuit 72, the seventh matching circuit 73, the eighth matching circuit 74, the first power amplifier 81, the second power amplifier 82, and the switch IC 800. Similarly to the high frequency module 1 according to the first embodiment, the high frequency module 1a includes the signal input terminals 91 and 92 and the signal output terminals 93 and 94 that are illustrated in FIG. 1.

The high frequency module 1a further includes, as illustrated in FIG. 4, the mounting substrate 100, the plurality of (in the example illustrated in the drawing, two) external connection terminals 200, a first resin layer 120 as the resin layer 120, a second resin layer 125, the shield layer 110, and a plurality of (in the example illustrated in the drawing, two) connection terminals 130.

The switch IC 800 and the plurality of connection terminals 130 are disposed on the second main surface 102 of the mounting substrate 100 (see FIG. 4). That is, at least part of the plurality of components is disposed on the first main surface 101 of the mounting substrate 100.

The plurality of connection terminals 130 are columnar electrodes. The plurality of connection terminals 130 are electrically connected to components disposed at the mounting substrate 100 and the conductive layer of the mounting substrate 100, with via conductors or other components provided at the mounting substrate 100 interposed therebetween.

The second resin layer 125 is disposed on the second main surface 102 of the mounting substrate 100. A part of the second resin layer 125 that is near the second main surface 102 of the mounting substrate 100 covers part of each of the plurality of electronic components mounted on the second main surface 102 of the mounting substrate 100 and the plurality of connection terminals 130. The second resin layer 125 is formed in such a manner that a tip surface of each of the plurality of connection terminals 130 is exposed. The second resin layer 125 includes resin (for example, epoxy resin). The second resin layer 125 may include a filler as well as resin. The second resin layer 125 may be made of the same material as the material of the first resin layer 120 or may be made of a material different from the material of the first resin layer 120.

The plurality of external connection terminals 200 include the first antenna terminal 11, the second antenna terminal 12, the one or more ground terminals, the signal input terminals 91 and 92, and the signal output terminals 93 and 94. The one or more ground terminals are connected to the ground layer of the mounting substrate 100, as described above. The ground layer is a circuit ground of the high frequency module 1a, and the plurality of electronic components of the high frequency module 1a include an electronic component connected to the ground layer. The plurality of external connection terminals 200 are disposed on a surface 1251 that is farther away from the mounting substrate 100, out of two surfaces of the second resin layer 125 that are opposite to each other in the thickness direction D1 of the mounting substrate 100. Specifically, the plurality of external connection terminals 200 are disposed on the surface 1251 immediately below the plurality of connection terminals 130. The plurality of external connection terminals 200 are electrically connected to the plurality of connection terminals 130 in a one-to-one relationship on the surface 1251.

As in the first embodiment, the shield layer 110 covers the main surface 121 of the first resin layer 120 that is far away from the mounting substrate 100, the outer peripheral surface 123 of the resin layer 120, and the outer peripheral surface 103 of the mounting substrate 100. Furthermore, the shield layer 110 covers at least part of an outer peripheral surface 126 of the second resin layer 125. In a fifth modification, the shield layer 110 covers at least part of the outer peripheral surface 126 of the second resin layer 125. The shield layer 110 is electrically connected to the ground terminal of the mounting substrate 100.

Also in the first modification, even when the first transmission-system component and the second transmission-system component that are connected to the shield layer 110 (ground electrode) perform a simultaneous transmission operation, deterioration of the characteristics can be suppressed.

### (4.2) Second Modification

A high frequency module 1b according to a second modification will be described with reference to FIG. 5. Regarding the high frequency module 1b according to the second modification, component elements similar to component elements of the high frequency module 1a according to the first modification will be denoted by the same signs as those in the first modification, and description of the similar component elements will be omitted in an appropriate manner.

The high frequency module 1b according to the second modification is different from the high frequency module 1a according to the first modification in that external connection terminals 200 as the plurality of external connection terminals 200 are ball bumps 250. Furthermore, the high frequency module 1b according to the second modification is different from the high frequency module 1a according to the first modification in that the high frequency module 1b does not include the second resin layer 125 of the high frequency module 1a according to the first modification. The high frequency module 1b according to the second modification may include an under fill part provided in the space between the switch IC 800 and the second main surface 102 of the mounting substrate 100.

The ball bumps 250 that are the plurality of external connection terminals 200 are made of, for example, gold, copper, or solder.

Some of the plurality of external connection terminals 200 may be external connection terminals 200 formed as the ball bumps 250 and the other external connection terminals 200 may be external connection terminals 200 formed in a rectangular column shape.

Also in the second modification, even when the first transmission-system component and the second transmission-system component that are connected to the shield layer 110 (ground electrode) perform a simultaneous transmission operation, deterioration of the characteristics can be suppressed.

### (4.3) Third Modification

Although the first transmission-system component is the first filter 51 and the second transmission-system component is the second filter 52 in the first embodiment, the first transmission-system component and the second transmission-system component are not necessarily the first filter 51 and the second filter 52, respectively.

The first transmission-system component may be the first power amplifier 81, and the second transmission-system component may be the second power amplifier 82. Alternatively, the first transmission-system component may be the first filter 51, and the second transmission-system component may be the second power amplifier 82. Still alternatively, the first transmission-system component may be the first power amplifier 81, and the second transmission-system component may be the second filter 52. That is, the first transmission-system component is the first filter 51 or the first power amplifier 81, and the second transmission-system component is the second filter 52 or the second power amplifier 82.

### (4.4) Fourth Modification

Although the third component is the third filter 53 in the first embodiment, the third component is not necessarily the third filter 53.

The third component only needs to be configured not to perform a simultaneous transmission operation together with the first transmission-system component and the second transmission-system component. For example, the third component may be a component connected to the third filter 53. That is, the third component may be any component that does not perform a simultaneous transmission operation together with the first transmission-system component and the second transmission-system component and is not disposed at a signal path through which the first transmission signal passes or a signal path through which the second transmission signal passes.

### (4.5) Fifth Modification

Although the top surface 53b of the third filter 53 as the third component is connected to the shield layer 110 in the first embodiment, the top surface 53b is not necessarily arranged as described above.

The top surface 53b of the third filter 53 as the third component is not necessarily connected to the shield layer 110.

### Second Embodiment

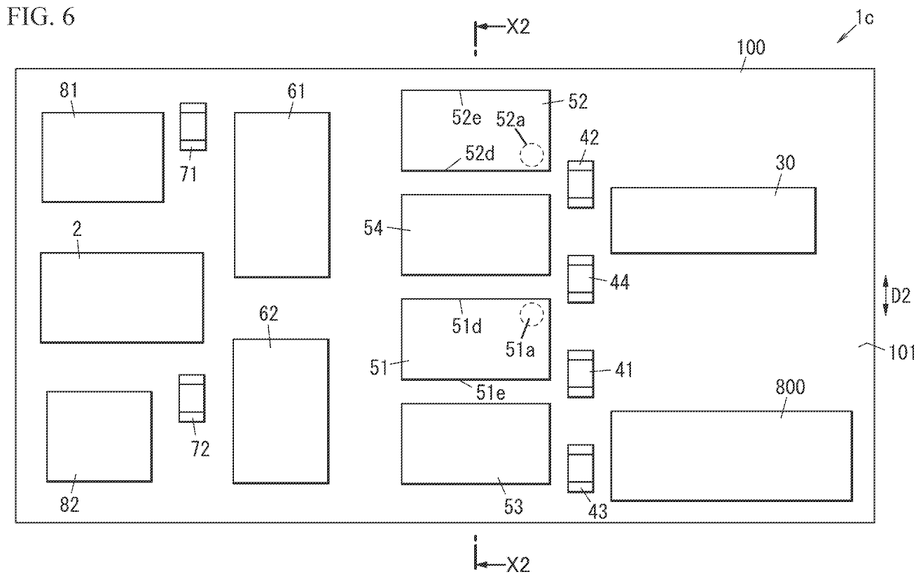

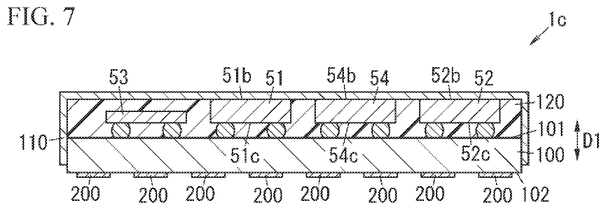

The second embodiment is different from the first embodiment in that a reception-system component is used as the third component. Features of the second embodiment that are different from the first embodiment will be mainly described below with reference to FIGS. 6 and 7. Component elements similar to component elements in the first embodiment will be denoted by the same signs as those in the first embodiment, and description of the similar component elements will be omitted in an appropriate manner.

In a high frequency module 1c according to the second embodiment, a plurality of components are disposed on the first main surface 101 of the mounting substrate 100. The plurality of components include the first switch 30, the first matching circuit 41, the second matching circuit 42, the third matching circuit 43, the fourth matching circuit 44, the first filter 51, the second filter 52, the third filter 53, the fourth filter 54, the second switch 61, the third switch 62, the fifth matching circuit 71, the sixth matching circuit 72, the seventh matching circuit 73, the eighth matching circuit 74, the first power amplifier 81, the second power amplifier 82, and the switch IC 800. The outer peripheral shape of each of the plurality of components in plan view from the thickness direction D1 of the mounting substrate 100 is a quadrilateral shape.

The plurality of components include the first component, the second component, and the third component. The first component is the first transmission-system component used for transmission of the first transmission signal and is, for example, the first filter 51. The second component is the second transmission-system component used for transmission of the second transmission signal and is, for example, the second filter 52. The third component is a reception-system component used for reception of a reception signal and is, for example, the fourth filter 54. The fourth filter 54 is a reception filter that allows a reception signal of Band 3 to be input to the second low noise amplifier 84 to pass therethrough.

In the second embodiment, the fourth filter 54 has two surfaces (top surface 54b and bottom surface 54c) that are opposite to each other in the thickness direction of the fourth filter (the thickness direction D1 of the mounting substrate 100) (see FIG. 7).

In the second embodiment, the top surface 51b of the first filter 51 and the top surface 52b of the second filter 52 are connected to the shield layer 110 (see FIG. 7). Furthermore, in the second embodiment, the top surface 54b of the fourth filter 54 is connected to the shield layer 110 (see FIG. 7).

In the second embodiment, the fourth filter 54 is disposed between the first filter 51 and the second filter 52 in plan view from the thickness direction D1 of the mounting substrate 100 (see FIG. 6). In the second embodiment, the first filter 51, the second filter 52, and the fourth filter 54 are arranged in such a manner that the fourth filter 54 is disposed between the first filter 51 and the second filter 52 along the direction D2 that is orthogonal to (intersects) the thickness direction D1.

More particularly, the first filter 51, the second filter 52, and the fourth filter 54 are arranged along a short side of the first filter 51 in plan view from the thickness direction D1 of the mounting substrate 100. Furthermore, the first filter 51, the second filter 52, and the fourth filter 54 are arranged along a short side of the second filter 52 in plan view from the thickness direction D1 of the mounting substrate 100. Moreover, the first filter 51, the second filter 52, and the fourth filter 54 are arranged along a short side of the fourth filter 54 in plan view from the thickness direction D1 of the mounting substrate 100. That is, in the second embodiment, the first filter 51, the second filter 52, and the fourth filter 54 are arranged along the short sides of the first filter 51, the second filter 52, and the fourth filter 54.

The input terminal 51a of the first filter 51 is arranged near the side 51d that is closer to the fourth filter 54, out of the two sides 51d and 51e of the first filter 51 that intersect the direction (direction D2) along which the first filter 51, the second filter 52, and the fourth filter 54 are arranged.

The input terminal 52a of the second filter 52 is arranged near the side 52d that is closer to the fourth filter 54, out of the two sides 52d and 52e of the second filter 52 that intersect the direction (direction D2) along which the first filter 51, the second filter 52, and the fourth filter 54 are arranged.

In the second embodiment, the reception-system component as the third component is disposed between the first transmission-system component and the second transmission-system component in plan view from the thickness direction D1 of the mounting substrate 100. Thus, compared to the case where the first transmission-system component and the second transmission-system component are adjacent to each other, mutual influence of heat generation at the first transmission-system component and the second transmission-system component is small. Consequently, in the high frequency module 1c according to the second embodiment, even when the first transmission-system component and the second transmission-system component that are connected to the shield layer 110 (ground electrode) perform a simultaneous transmission operation, deterioration of the characteristics can be suppressed.

The first and second modifications of the first embodiment may be applied to the second embodiment. That is, in the second embodiment, a component may be disposed on the second main surface 102 of the mounting substrate 100.

Furthermore, the third modification of the first embodiment may be applied to the second embodiment. That is, as in the first embodiment, the first transmission-system component is the first filter 51 or the first power amplifier 81 and the second transmission-system component is the second filter 52 or the second power amplifier 82 in the second embodiment.

Furthermore, although the third component is the fourth filter 54 in the second embodiment, the third component is not necessarily the fourth filter 54. The third component may be any component that operates at the time of reception and may be a component (for example, the switch IC 800) that is other than the fourth filter 54 and is disposed at, for example, a path through which a reception signal of Band 3 passes.

Furthermore, although the top surface 54b of the fourth filter 54 as the third component is connected to the shield layer 110 in the second embodiment, the top surface 54b is not necessarily arranged as described above. The top surface 54b of the fourth filter 54 as the third component is not necessarily connected to the shield layer 110.

### Third Embodiment

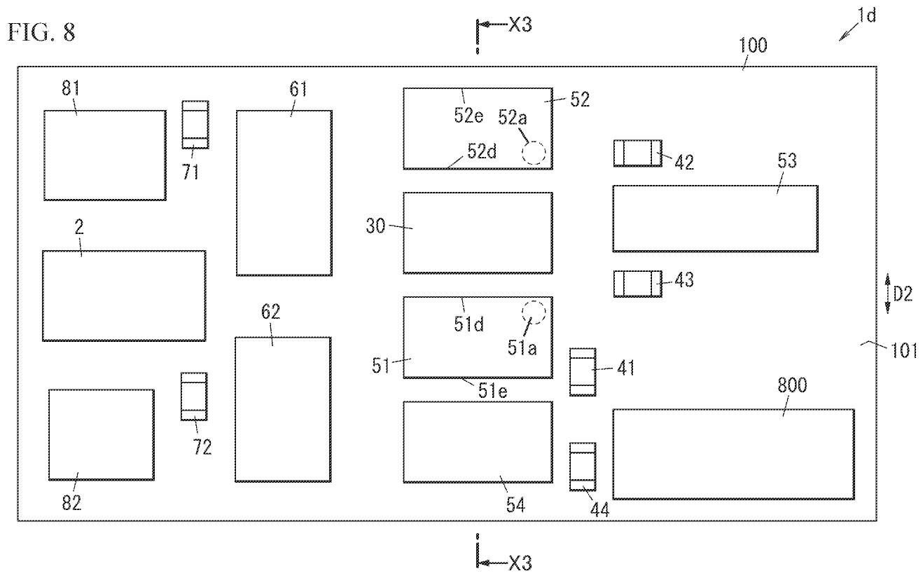

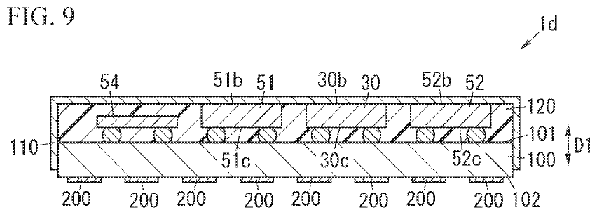

A third embodiment is different from the second embodiment in that the first switch 30, which is a reception-system component, is used as the third component. Features of the third embodiment that are different from the second embodiment will be mainly described below with reference to FIGS. 8 and 9. Component elements similar to component elements in the first and second embodiments will be denoted by the same signs as those in the first and second embodiments, and description of the similar component elements will be omitted in an appropriate manner.

In a high frequency module 1d according to the third embodiment, a plurality of components are disposed on the first main surface 101 of the mounting substrate 100. The plurality of components include the first switch 30, the first matching circuit 41, the second matching circuit 42, the third matching circuit 43, the fourth matching circuit 44, the first filter 51, the second filter 52, the third filter 53, the fourth filter 54, the second switch 61, the third switch 62, the fifth matching circuit 71, the sixth matching circuit 72, the seventh matching circuit 73, the eighth matching circuit 74, the first power amplifier 81, the second power amplifier 82, and the switch IC 800. The outer peripheral shape of each of the plurality of components in plan view from the thickness direction D1 of the mounting substrate 100 is a quadrilateral shape.

The plurality of components include the first component, the second component, and the third component. The first component is the first transmission-system component used for transmission of the first transmission signal and is, for example, the first filter 51. The second component is the second transmission-system component used for transmission of the second transmission signal and is, for example, the second filter 52. The third component is the reception-system component used for reception of a reception signal and is, for example, the first switch 30. At the time of reception of a signal of Band 3, the first switch 30 allows the reception signal of Band 3 to pass therethrough.

In the third embodiment, the first switch 30 has two surfaces (top surface 30b and bottom surface 30c) that are opposite to each other in the thickness direction of the first switch 30 (the thickness direction D1 of the mounting substrate 100) (see FIG. 9).

In the third embodiment, the top surface 51b of the first filter 51 and the top surface 52b of the second filter 52 are connected to the shield layer 110 (see FIG. 9). Furthermore, in the third embodiment, the top surface 30b of the first switch 30 is connected to the shield layer 110 (see FIG. 9).

In the third embodiment, the first switch 30 is disposed between the first filter 51 and the second filter 52 in plan view from the thickness direction D1 of the mounting substrate 100 (see FIG. 8). In the third embodiment, the first filter 51, the second filter 52, and the first switch 30 are arranged in such a manner that the first switch 30 is disposed between the first filter 51 and the second filter 52 along the direction D2 that is orthogonal to (intersects) the thickness direction D1.

More particularly, the first filter 51, the second filter 52, and the first switch 30 are arranged along a short side of the first filter 51 in plan view from the thickness direction D1 of the mounting substrate 100. Furthermore, the first filter 51, the second filter 52, and the first switch 30 are arranged along a short side of the second filter 52 in plan view from the thickness direction D1 of the mounting substrate 100. Moreover, the first filter 51, the second filter 52, and the first switch 30 are arranged along a short side of the first switch 30 in plan view from the thickness direction D1 of the mounting substrate 100. That is, in the third embodiment, the first filter 51, the second filter 52, and the first switch 30 are arranged along the short sides of the first filter 51, the second filter 52, and the first switch 30.

The input terminal 51a of the first filter 51 is arranged near the side 51d that is closer to the first switch 30, out of the two sides 51d and 51e of the first filter 51 that intersect the direction (direction D2) along which the first filter 51, the second filter 52, and the first switch 30 are arranged.

The input terminal 52a of the second filter 52 is arranged near the side 52d that is closer to the first switch 30, out of the two sides 52d and 52e of the second filter 52 that intersect the direction (direction D2) along which the first filter 51, the second filter 52, and the first switch 30 are arranged.

According to the third embodiment, the first switch 30 as the third component is disposed between the first transmission-system component and the second transmission-system component in plan view from the thickness direction D1 of the mounting substrate 100. Thus, compared to the case where the first transmission-system component and the second transmission-system component are adjacent to each other, mutual influence of heat generation at the first transmission-system component and the second transmission-system component is small. Consequently, in the high frequency module 1d according to the third embodiment, even when the first transmission-system component and the second transmission-system component that are connected to the shield layer 110 (ground electrode) perform a simultaneous transmission operation, deterioration of the characteristics can be suppressed.

The first and second modifications of the first embodiment may be applied to the third embodiment. That is, in the third embodiment, a component may be disposed on the second main surface 102 of the mounting substrate 100.

Furthermore, the third modification of the first embodiment may be applied to the third embodiment. That is, as in the first embodiment, the first transmission-system component is the first filter 51 or the first power amplifier 81 and the second transmission-system component is the second filter 52 or the second power amplifier 82 in the third embodiment.

Furthermore, although the top surface 30b of the first switch 30 as the third component is connected to the shield layer 110 in the third embodiment, the top surface 30b is not necessarily arranged as described above. The top surface 30b of the first switch 30 as the third component is not necessarily connected to the shield layer 110.

### Fourth Embodiment

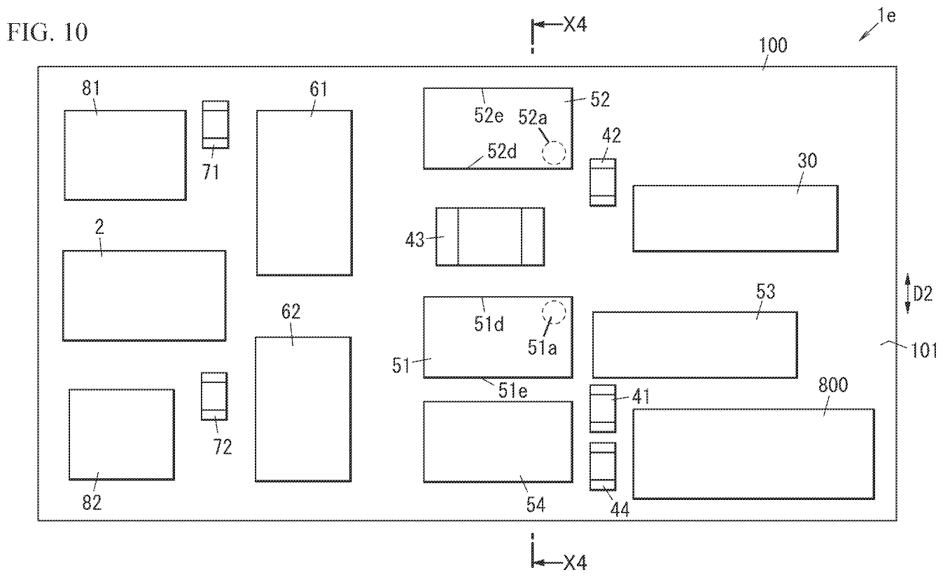

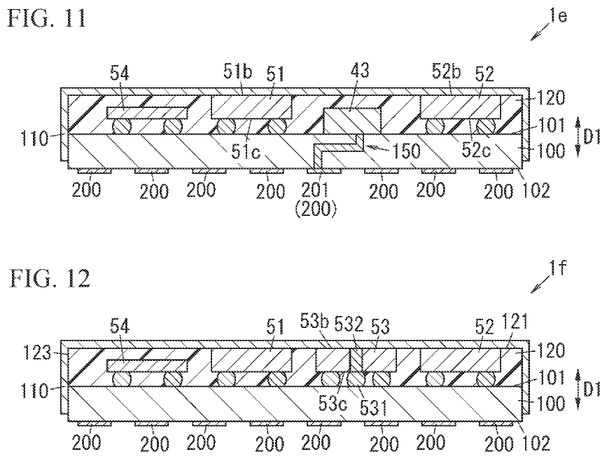

A fourth embodiment is different from the first embodiment in that a matching circuit is used as the third component. Features of the fourth embodiment that are different from the first embodiment will be mainly described below with reference to FIGS. 10 and 11. Component elements similar to component elements in the first to third embodiments will be denoted by the same signs as those in the first to third embodiments, and description of the similar component elements will be omitted in an appropriate manner.

In a high frequency module 1e according to the fourth embodiment, a plurality of components are disposed on the first main surface 101 of the mounting substrate 100. The plurality of components include the first switch 30, the first matching circuit 41, the second matching circuit 42, the third matching circuit 43, the fourth matching circuit 44, the first filter 51, the second filter 52, the third filter 53, the fourth filter 54, the second switch 61, the third switch 62, the fifth matching circuit 71, the sixth matching circuit 72, the seventh matching circuit 73, the eighth matching circuit 74, the first power amplifier 81, the second power amplifier 82, and the switch IC 800. The outer peripheral shape of each of the plurality of components in plan view from the thickness direction D1 of the mounting substrate 100 is a quadrilateral shape.

The plurality of components include the first component, the second component, and the third component. The first component is the first transmission-system component used for transmission of the first transmission signal and is, for example, the first filter 51. The second component is the second transmission-system component used for transmission of the second transmission signal and is, for example, the second filter 52. The third component is a matching circuit that does not perform a simultaneous transmission operation together with the first transmission-system component and the second transmission-system component and is, for example, the third matching circuit 43.

In the fourth embodiment, the top surface 51b of the first filter 51 and the top surface 52b of the second filter 52 are connected to the shield layer 110 (see FIG. 11).

In the fourth embodiment, the third matching circuit 43 is disposed between the first filter 51 and the second filter 52 in plan view from the thickness direction D1 of the mounting substrate 100 (see FIG. 10). In the fourth embodiment, the first filter 51, the second filter 52, and the third matching circuit 43 are arranged in such a manner that the third matching circuit 43 is disposed between the first filter 51 and the second filter 52 along the direction D2 that is orthogonal to (intersects) the thickness direction D1.

More particularly, the first filter 51, the second filter 52, and the third matching circuit 43 are arranged along a short side of the first filter 51 in plan view from the thickness direction D1 of the mounting substrate 100. Furthermore, the first filter 51, the second filter 52, and the third matching circuit 43 are arranged along a short side of the second filter 52 in plan view from the thickness direction D1 of the mounting substrate 100. Moreover, the first filter 51, the second filter 52, and the third matching circuit 43 are arranged along a short side of the third matching circuit 43 in plan view from the thickness direction D1 of the mounting substrate 100. That is, in the third embodiment, the first filter 51, the second filter 52, and the third matching circuit 43 are arranged along the short sides of the first filter 51, the second filter 52, and the third matching circuit 43.

The input terminal 51a of the first filter 51 is arranged near the side 51d that is closer to the third matching circuit 43, out of the two sides 51d and 51e of the first filter 51 that intersect the direction (direction D2) along which the first filter 51, the second filter 52, and the first switch 30 are arranged.

The input terminal 52a of the second filter 52 is arranged near the side 52d that is closer to the third matching circuit 43, out of the two sides 52d and 52e of the second filter 52 that intersect the direction (direction D2) along which the first filter 51, the second filter 52, and the first switch 30 are arranged.

The plurality of external connection terminals 200 of the high frequency module 1e according to the fourth embodiment include a ground terminal 201 that is connected to the ground. One end of the third matching circuit 43 is electrically connected to the ground terminal 201 with a path (ground path 150) connected to the ground terminal 201 interposed therebetween. In other words, the ground terminal 201 is electrically connected to the one end of the third matching circuit 43. The ground path 150 is a path including one or more via conductors and one or more ground layers.

The ground terminal 201 is disposed between the first component and the second component in plan view from the thickness direction D1 of the mounting substrate 100.

According to the fourth embodiment, a matching circuit (for example, the third matching circuit 43) as the third component is disposed between the first transmission-system component and the second transmission-system component in plan view from the thickness direction D1 of the mounting substrate 100. Thus, compared to the case where the first transmission-system component and the second transmission-system component are adjacent to each other, mutual influence of heat generation at the first transmission-system component and the second transmission-system component is small. Consequently, in the high frequency module 1e according to the fourth embodiment, even when the first transmission-system component and the second transmission-system component that are connected to the shield layer 110 (ground electrode) perform a simultaneous transmission operation, deterioration of the characteristics can be suppressed.

The first and second modifications of the first embodiment may be applied to the fourth embodiment. That is, in the fourth embodiment, components may be disposed on the second main surface 102 of the mounting substrate 100.

Furthermore, the third modification of the first embodiment may be applied to the fourth embodiment. That is, as in the first embodiment, the first transmission-system component is the first filter 51 or the first power amplifier 81 and the second transmission-system component is the second filter 52 or the second power amplifier 82 in the fourth embodiment.

Furthermore, although the third matching circuit 43 as the third component is disposed between the first transmission-system component and the second transmission-system component in the fourth embodiment, the third matching circuit 43 is not necessarily arranged as described above. In the fourth embodiment, the third component only needs to be a matching circuit that does not perform a simultaneous transmission operation together with the first transmission-system component and the second transmission-system component. Alternatively, the third component may be a matching circuit that operates at the time of transmission, for example, any one of the fourth matching circuit 44, the seventh matching circuit 73, and the eighth matching circuit 74. That is, the third component only needs to be a matching circuit that is provided at a path that is different from a path through which the first transmission signal passes and a path through which the second transmission signal passes.

Furthermore, although one end of the matching circuit (third matching circuit 43) as the third component is connected to the ground, that is, shunt connection is employed in the fourth embodiment, the matching circuit is not necessarily arranged as described above. The matching circuit as the third component may be connected in series between two components for which the matching circuit performs impedance matching.

### Fifth Embodiment

A fifth embodiment is different from the first embodiment in that the third component includes a through-hole via. Features of the fifth embodiment that are different from the first embodiment will be mainly described below with reference to FIG. 12. Component elements similar to component elements in the first to fourth embodiments will be denoted by the same signs as those in the first to fourth embodiments, and description of the similar component elements will be omitted in an appropriate manner. In a high frequency module if according to the fifth embodiment, a plurality of components are disposed on the first main surface 101 of the mounting substrate 100. The plurality of components include the first switch 30, the first matching circuit 41, the second matching circuit 42, the third matching circuit 43, the fourth matching circuit 44, the first filter 51, the second filter 52, the third filter 53, the fourth filter 54, the second switch 61, the third switch 62, the fifth matching circuit 71, the sixth matching circuit 72, the seventh matching circuit 73, the eighth matching circuit 74, the first power amplifier 81, the second power amplifier 82, and the switch IC 800. The outer peripheral shape of each of the plurality of components in plan view from the thickness direction D1 of the mounting substrate 100 is a quadrilateral shape.

The plurality of components include the first component, the second component, and the third component. The first component is the first transmission-system component used for transmission of the first transmission signal and is, for example, the first filter 51. The second component is the second transmission-system component used for transmission of the second transmission signal and is, for example, the second filter 52. The third component is a component that does not perform a simultaneous transmission operation together with the first transmission-system component and the second transmission-system component and is, for example, the third filter 53.

The third filter 53 includes a ground terminal 531 that is electrically connected to the ground. The third filter 53 includes a through-hole via 532. The through-hole via 532 penetrates between the top surface 53b and the bottom surface 53c of the third filter. That is, the through-hole via 532 is provided at the third filter 53 along the thickness direction D1 of the mounting substrate 100. One end of the through-hole via 532 is electrically connected to the ground terminal 531, and the other end of the through-hole via 532 is connected to the shield layer 110. Thus, the ground terminal 531 is electrically connected to the shield layer 110. The through-hole via 532 is, for example, a silicon through-hole via.

According to the fifth embodiment, the third component is disposed between the first transmission-system component and the second transmission-system component in plan view from the thickness direction D1 of the mounting substrate 100. Thus, compared to the case where the first transmission-system component and the second transmission-system component are adjacent to each other, mutual influence of heat generation at the first transmission-system component and the second transmission-system component is small. Consequently, in the high frequency module if according to the fifth embodiment, even when the first transmission-system component and the second transmission-system component that are connected to the shield layer 110 (ground electrode) perform a simultaneous transmission operation, deterioration of the characteristics can be suppressed. Furthermore, with the third component (in this example, the third filter 53) including the through-hole via (through-hole via 532), isolation between the first transmission-system component and the second transmission-system component can be prevented from decreasing.

The first and second modifications of the first embodiment may be applied to the fifth embodiment. That is, in the fifth embodiment, a component may be disposed on the second main surface 102 of the mounting substrate 100.

Furthermore, the third modification of the first embodiment may be applied to the fifth embodiment. That is, as in the first embodiment, the first transmission-system component is the first filter 51 or the first power amplifier 81 and the second transmission-system component is the second filter 52 or the second power amplifier 82 in the fifth embodiment.

The fifth embodiment may be applied to the second and third embodiments. That is, at the reception-system component (for example, the fourth filter 54 or the first switch 30) as the third component, a through-hole via that electrically connects a ground terminal of the reception-system component with the shield layer 110 may be provided.

### Other Modifications

In each of the embodiments described above, the combination of the frequency band of the first transmission signal and the frequency band of the second transmission signal is the combination of Band 3 based on the 4G standards and n41 based on the 5G standards. However, the combination of the frequency band of the first transmission signal and the frequency band of the second transmission signal is not limited to the combination described above. The combination of the frequency band of the first transmission signal and the frequency band of the second transmission signal is any one of the combination of Band 1 based on the 4G standards and n40 based on the 5G standards, the combination of Band 3 based on the 4G standards and n40 based on the 5G standards, the combination of Band 1 based on the 4G standards and n41 based on the 5G standards, the combination of Band 3 based on the 4G standards and n41 based on the 5G standards, the combination of Band 39 based on the 4G standards and n41 based on the 5G standards, the combination of Band 66 based on the 4G standards and n41 based on the 5G standards, and the combination of Band 25 based on the 4G standards and n41 based on the 5G standards. Furthermore, the combination of the frequency band of the first transmission signal and the frequency band of the second transmission signal is not limited to the combination of a frequency band based on the 4G standards and a frequency band based on the 5G standards. The combination of the frequency band of the first transmission signal and the frequency band of the second transmission signal may be the combination of frequency bands based on the 4G standards or the combination of frequency bands based on the 5G standards. For example, combinations of 4G frequency bands include the combination of Band 1 and Band 3, the combination of Band 1 and Band 28, the combination of Band 1 and Band 77, the combination of Band 1 and Band 78, the combination of Band 3 and Band 20, the combination of Band 3 and Band 28, the combination of Band 3 and Band 41, the combination of Band 3 and Band 78, the combination of Band 7 and Band 78, the combination of Band 8 and Band 78, the combination of Band 20 and Band 78, the combination of Band 28 and Band 77, and the combination of Band 28 and Band 78.

Furthermore, in the embodiments, the high frequency modules 1 to if each includes a plurality of antenna terminals (first antenna terminal 11 and second antenna terminal 12). However, the high frequency modules 1 to if do not necessarily include a plurality of antenna terminals. Each of the high frequency modules 1 to if may include a single antenna terminal. That is, each of the high frequency modules 1 to if may transmit the first transmission signal and the second transmission signal via a single antenna.

Furthermore, in the embodiments, each of the high frequency modules 1 to if is configured to perform transmission of two transmission signals as simultaneous transmission. However, each of the high frequency modules 1 to if is not necessarily configured to perform simultaneous transmission of two transmission signals. Each of the high frequency modules 1 to if may be configured to perform simultaneous transmission of three or more signals. For example, for simultaneous transmission of three signals, a component that is not used for a simultaneous transmission operation for three signals is disposed between two transmission-system components that allow two of the three signals to pass therethrough. That is, a component different from each of the components that allow corresponding three signals to pass therethrough is disposed between two transmission-system components that allow two of the three signals to pass therethrough. Alternatively, a reception-system component, that is, a reception filter used for reception of a reception signal, a switch, or the like, is disposed between two transmission-system components that allow two of the three signals to pass therethrough. Still alternatively, a matching circuit provided at a path different from each of the paths through which corresponding three signals pass is disposed between two transmission-system components that allow two of the three signals to pass therethrough.

### Conclusion

As described above, according to a first aspect, a high frequency module (1; 1a; 1b; 1e; 1f) includes a mounting substrate (100), a plurality of components, a resin layer (120), and a ground electrode (for example, the shield layer 110). The mounting substrate (100) has a first main surface (101) and a second main surface (102) that are opposite to each other. The plurality of components are disposed on the first main surface (101). The resin layer (120) covers at least part of the plurality of components. The ground electrode covers at least part of the resin layer (120). The plurality of components include a first component, a second component, and a third component. The first component is any one of a first filter (51) and a first power amplifier (81) that are used for transmission of a first transmission signal. The second component is any one of a second filter (52) and a second power amplifier (82) that are used for transmission of a second transmission signal of a frequency band different from a frequency band of the first transmission signal. A top surface (for example, the top surface 51b) of the first component and a top surface (for example, the top surface 52b) of the second component are connected to the ground electrode. The first component and the second component are configured to be capable of performing simultaneous transmission. The third component is configured not to perform a simultaneous transmission operation together with the first component and the second component. The third component is disposed between the first component and the second component in plan view from a thickness direction (D1) of the mounting substrate (100).

With this arrangement, even when the first component and the second component that are connected to the ground electrode perform a simultaneous transmission operation, deterioration of characteristics can be suppressed.

According to a second aspect, a high frequency module (1c; 1d; 1e; 1f) includes a mounting substrate (100), a plurality of components, a resin layer (120), and a ground electrode (for example, the shield layer 110). The mounting substrate (100) has a first main surface (101) and a second main surface (102) that are opposite to each other. The plurality of components are disposed on the first main surface (101). The resin layer (120) covers at least part of the plurality of components. The ground electrode covers at least part of the resin layer (120). The plurality of components include a first component, a second component, and a third component. The first component is any one of a first filter (51) and a first power amplifier (81) that are used for transmission of a first transmission signal. The second component is any one of a second filter (52) and a second power amplifier (82) that are used for transmission of a second transmission signal of a frequency band different from a frequency band of the first transmission signal. The third component is a reception-system component that is used for reception of a reception signal. A top surface (for example, the top surface 51b) of the first component and a top surface (for example, the top surface 52b) of the second component are connected to the ground electrode. The first component and the second component are configured to be capable of performing simultaneous transmission. The reception-system component is disposed between the first component and the second component in plan view from a thickness direction (D1) of the mounting substrate (100).

With this arrangement, even when the first component and the second component that are connected to the ground electrode perform a simultaneous transmission operation, deterioration of characteristics can be suppressed.

According to a third aspect, the high frequency module (1c; 1d; 1e; 1f) according to the second aspect includes an antenna terminal (for example, the first antenna terminal 11 or the second antenna terminal 12) and a switch IC (for example, the first switch 30). The switch IC includes a switch for switching a connection destination for the antenna terminal. The reception-system component is the switch IC.

With this arrangement, since the switch IC is disposed between the first component and the second component, even when the first component and the second component perform a simultaneous transmission operation, deterioration of the characteristics can be suppressed.

According to a fourth aspect, in the high frequency module (1; 1a; 1b; 1c; 1d; 1e; 1f) according to the first or second aspect, the third component is a reception filter (for example, the fourth filter 54) that is used for reception of a reception signal.

With this arrangement, since the reception filter is disposed between the first component and the second component, even when the first component and the second component perform a simultaneous transmission operation, deterioration of the characteristics can be suppressed.

According to a fifth aspect, in the high frequency module (1; 1a; 1b; 1c; 1d; 1e; 1f) according to any one of the first to fourth aspects, the third component includes a ground terminal (531) that is connected to a ground. The third component includes a through-hole via (532). The ground terminal (531) is connected to the ground electrode (shield layer 110) with the through-hole via (532) interposed therebetween.

With this arrangement, even when the first component and the second component perform a simultaneous transmission operation, deterioration of characteristics caused by heat dissipation from the first component and the second component can be suppressed. Furthermore, due to connection between the third component and the ground electrode, isolation between the first component and the second component can be prevented from decreasing.

According to a sixth aspect, in the high frequency module (1; 1a; 1b; 1c; 1d; 1e; 1f) according to the first or second aspect, the third component is a matching circuit (for example, the third matching circuit 43) that is provided at a path different from a path through which the first transmission signal passes and a path through which the second transmission signal passes.

With this arrangement, since the matching circuit is disposed between the first component and the second component, even when the first component and the second component perform a simultaneous transmission operation, deterioration of the characteristics can be suppressed.

According to a seventh aspect, the high frequency module (1; 1a; 1b; 1c; 1d; 1e; 1f) according to the sixth aspect further includes a ground terminal (201). The ground terminal (201) is connected to one end of the matching circuit, disposed on the second main surface (102) of the mounting substrate (100), and connected to a ground. The ground terminal (201) is disposed between the first component and the second component in plan view from the thickness direction (D1) of the mounting substrate (100).

With this arrangement, even when the first component and the second component perform a simultaneous transmission operation, deterioration of the characteristics caused by heat dissipation from the first component and the second component can be suppressed. Furthermore, since the one end of the matching circuit as the third component is connected to the ground with the ground terminal (201) interposed therebetween, the isolation between the first component and the second component can be prevented from decreasing.

According to an eighth aspect, in the high frequency module (1; 1a; 1b; 1c; 1d; 1e; 1f) according to any one of the first to seventh aspects, a top surface of the third component (for example, the top surface 53b of the third filter 53) is connected to the ground electrode (shield layer 110).

With this arrangement, even when the first component and the second component perform a simultaneous transmission operation, deterioration of the characteristics caused by heat dissipation from the first component and the second component can be suppressed.

According to a ninth aspect, in the high frequency module (1; 1a; 1b; 1c; 1d; 1e; 1f) according to any one of the first to eighth aspects, the first component, the second component, and the third component are arranged along a short side of the first component in plan view from the thickness direction (D1) of the mounting substrate (100). The third component is arranged in such a manner that a long side of the third component intersects a direction (for example, the direction D2) along the short side of the first component.

With this arrangement, since the third component is arranged in such a manner that the long side of the third component intersects the direction (for example, the direction D2) along the short side of the first component, heat conduction between the first component and the second component can be blocked. As a result, even when the first component and the second component perform a simultaneous transmission operation, deterioration of the characteristics caused by heat dissipation from the first component and the second component can be suppressed.

According to a tenth aspect, in the high frequency module (1; 1a; 1b; 1c; 1d; 1e; 1f) according to any one of the first to ninth aspects, the first component, the second component, and the third component are arranged along a short side of the second component in plan view from the thickness direction (D1) of the mounting substrate (100).

With this arrangement, even when the first component and the second component perform a simultaneous transmission operation, deterioration of the characteristics caused by heat dissipation from the first component and the second component can be suppressed.

According to an eleventh aspect, in the high frequency module (1; 1a; 1b; 1c; 1d; 1e; 1f) according to any one of the first to tenth aspects, the first component includes an input terminal (for example, the input terminal 51a) to which the first transmission signal is input. The input terminal of the first component is arranged near a side (for example, the side 51d) that is closer to the third component, out of two sides (for example, the sides 51d and 51e) of the first component that intersect a direction (for example, the direction D2) along which the first component, the second component, and the third component are arranged.

With this arrangement, since the input terminal of the first component is arranged near the third component, even when the first component and the second component perform a simultaneous transmission operation, deterioration of the characteristics caused by heat dissipation from the first component and the second component can be suppressed.

According to a twelfth aspect, in the high frequency module (1; 1a; 1b; 1c; 1d; 1e; 1f) according to any one of the first to eleventh aspects, the second component includes an input terminal (for example, the input terminal 52a) to which the second transmission signal is input. The input terminal of the second component is arranged near a side (for example, the side 52d) that is closer to the third component, out of two sides (for example, the sides 52d and 52e) of the second component that intersect a direction (for example, the direction D2) along which the first component, the second component, and the third component are arranged.

With this arrangement, since the input terminal of the second component is arranged near the third component, even when the first component and the second component perform a simultaneous transmission operation, deterioration of the characteristics caused by heat dissipation from the first component and the second component can be suppressed.

According to a thirteenth aspect, in the high frequency module (1; 1a; 1b; 1c; 1d; 1e; 1f) according to any one of the first to twelfth aspects, the frequency band of the first transmission signal is a frequency band based on 4G standards. The frequency band of the second transmission signal is a frequency band based on 5G standards.

With this arrangement, in a simultaneous transmission operation using the frequency band based on the 4G standards and the frequency band based on the 5G standards, deterioration of the characteristics can be suppressed.

According to a fourteenth aspect, in the high frequency module (1; 1a; 1b; 1c; 1d; 1e; 1f) according to the thirteenth aspect, a combination of the frequency band of the first transmission signal and the frequency band of the second transmission signal is any one of a combination of Band 1 and n40, a combination of Band 3 and n40, a combination of Band 1 and n41, a combination of Band 3 and n41, a combination of Band 39 and n41, a combination of Band 66 and n41, and a combination of Band 25 and n41.

With this arrangement, in a simultaneous transmission operation using any one of the combinations of the frequency bands mentioned above, deterioration of the characteristics can be suppressed.

According to a fifteenth aspect, a high frequency module (1; 1a; 1b; 1e; 1f) includes a mounting substrate (100), a plurality of components, a resin layer (120), and a ground electrode (for example, the shield layer 110). The mounting substrate (100) has a first main surface (101) and a second main surface (102) that are opposite to each other. The plurality of components are disposed on the first main surface (101). The resin layer (120) covers at least part of the plurality of components. The ground electrode covers at least part of the resin layer (120). The plurality of components include a first component, a second component, and a third component. The first component is any one of a first filter (51) and a first power amplifier (81) that are used for transmission of a first transmission signal. The second component is any one of a second filter (52) and a second power amplifier (82) that are used for transmission of a second transmission signal of a frequency band different from a frequency band of the first transmission signal. A top surface (for example, the top surface 51b) of the first component and a top surface (for example, the top surface 52b) of the second component are connected to the ground electrode. The third component is configured not to perform a simultaneous transmission operation together with the first component and the second component. The third component is disposed between the first component and the second component in plan view from a thickness direction (D1) of the mounting substrate (100). A combination of the frequency band of the first transmission signal and the frequency band of the second transmission signal is any one of a combination of Band 1 based on 4G standards and n40 based on 5G standards, a combination of Band 3 based on the 4G standards and n40 based on the 5G standards, a combination of Band 1 based on the 4G standards and n41 based on the 5G standards, a combination of Band 3 based on the 4G standards and n41 based on the 5G standards, a combination of Band 39 based on the 4G standards and n41 based on the 5G standards, a combination of Band 66 based on the 4G standards and n41 based on the 5G standards, and a combination of Band 25 based on the 4G standards and n41 based on the 5G standards.

With this arrangement, even when the first component and the second component that are connected to the ground electrode perform a simultaneous transmission operation, deterioration of characteristics can be suppressed.

According to a sixteenth aspect, a high frequency module (1c; 1d; 1e; 1f) includes a mounting substrate (100), a plurality of components, a resin layer (120), and a ground electrode (for example, the shield layer 110). The mounting substrate (100) has a first main surface (101) and a second main surface (102) that are opposite to each other. The plurality of components are disposed on the first main surface (101). The resin layer (120) covers at least part of the plurality of components. The ground electrode covers at least part of the resin layer (120). The plurality of components include a first component, a second component, and a third component. The first component is any one of a first filter (51) and a first power amplifier (81) that are used for transmission of a first transmission signal. The second component is any one of a second filter (52) and a second power amplifier (82) that are used for transmission of a second transmission signal of a frequency band different from a frequency band of the first transmission signal. The third component is a reception-system component that is used for reception of a reception signal. A top surface (for example, the top surface 51b) of the first component and a top surface (for example, the top surface 52b) of the second component are connected to the ground electrode. The reception-system component is disposed between the first component and the second component in plan view from a thickness direction (D1) of the mounting substrate (100). A combination of the frequency band of the first transmission signal and the frequency band of the second transmission signal is any one of a combination of Band 1 based on 4G standards and n40 based on 5G standards, a combination of Band 3 based on the 4G standards and n40 based on the 5G standards, a combination of Band 1 based on the 4G standards and n41 based on the 5G standards, a combination of Band 3 based on the 4G standards and n41 based on the 5G standards, a combination of Band 39 based on the 4G standards and n41 based on the 5G standards, a combination of Band 66 based on the 4G standards and n41 based on the 5G standards, and a combination of Band 25 based on the 4G standards and n41 based on the 5G standards.

With this arrangement, even when the first component and the second component that are connected to the ground electrode perform a simultaneous transmission operation, deterioration of characteristics can be suppressed.

According to a seventeenth aspect, a communication apparatus (500) includes the high frequency module (1; 1a; 1b; 1c; 1d; 1e; 1f) according to any one of the first to sixteenth aspects and a signal processing circuit (501). The signal processing circuit (501) processes the first transmission signal and the second transmission signal that pass through the high frequency module (1; 1a; 1b; 1c; 1d; 1e; 1f).

With this arrangement, even when the first component and the second component that are connected to the ground electrode perform a simultaneous transmission operation, deterioration of characteristics can be suppressed.

### REFERENCE SIGNS LIST

1, 1a, 1b, 1c, 1d, 1e, 1f high frequency module
2 controller
11 first antenna terminal (antenna terminal)
12 second antenna terminal (antenna terminal)
21 first low pass filter
22 second low pass filter
30 first switch
30b, 51b, 52b, 53b, 54b top surface
30c, 51c, 52c, 53c, 54c bottom surface
31 first terminal
32 second terminal
33 third terminal
34 fourth terminal
35 fifth terminal
36 sixth terminal
41 first matching circuit
42 second matching circuit
43 third matching circuit
44 fourth matching circuit
51 first filter
51a, 52a input terminal
51d, 51e, 52d, 52e side
52 second filter
53 third filter
54 fourth filter
61 second switch
62 third switch
71 fifth matching circuit
72 sixth matching circuit
73 seventh matching circuit
74 eighth matching circuit
81 first power amplifier
82 second power amplifier
83 first low noise amplifier
84 second low noise amplifier
85 fourth switch
91, 92 signal input terminal
93, 94 signal output terminal
100 mounting substrate
101 first main surface
102 second main surface
103, 123, 126 outer peripheral surface
110 shield layer
120 resin layer (first resin layer)
121 main surface
125 second resin layer
130 connection terminal
150 ground path
200 external connection terminal
201 ground terminal
250 ball bump
500 communication apparatus
501 signal processing circuit
502 RF signal processing circuit
503 baseband signal processing circuit
511 first antenna
512 second antenna
531 ground terminal
532 through-hole via
611 common terminal
612, 613, 614 selection terminal
621 common terminal
622, 623, 624, 625, 626, 627 selection terminal
851 first terminal
852 second terminal
853 third terminal
854 fourth terminal
855 fifth terminal
856 sixth terminal
1251 surface
D1 thickness direction
D2 direction
800 switch IC

1. A high frequency module comprising:
a mounting substrate that has a first main surface and a second main surface that are opposite to each other;
a plurality of components that are on the first main surface;
a resin layer that covers at least part of the plurality of components; and
a ground electrode that covers at least part of the resin layer,
wherein the plurality of components comprises a first component, a second component, and a third component,
wherein the first component is a first transmission filter or a first transmission power amplifier for a first transmission signal,
wherein the second component is a second transmission filter or a second transmission power amplifier for a second transmission signal of a frequency band different from a frequency band of the first transmission signal,
wherein a top surface of the first component and a top surface of the second component are connected to the ground electrode,
wherein the first component and the second component are configured to perform simultaneous transmission,
wherein the third component is configured not to perform a simultaneous transmission operation together with the first component and the second component, and
wherein the third component is between the first component and the second component in a plan view from a thickness direction of the mounting substrate.

2. A high frequency module comprising:
a mounting substrate that has a first main surface and a second main surface that are opposite to each other;
a plurality of components that are on the first main surface;
a resin layer that covers at least part of the plurality of components; and
a ground electrode that covers at least part of the resin layer,
wherein the plurality of components comprises a first component, a second component, and a third component,
wherein the first component is a first transmission filter or a first transmission power amplifier for a first transmission signal,
wherein the second component is a second transmission filter or a second transmission power amplifier for a second transmission signal of a frequency band different from a frequency band of the first transmission signal,
wherein the third component is a reception-system component for a reception signal,
wherein a top surface of the first component and a top surface of the second component are connected to the ground electrode,
wherein the first component and the second component are configured to perform simultaneous transmission, and
wherein the reception-system component is between the first component and the second component in a plan view from a thickness direction of the mounting substrate.

3. The high frequency module according to claim 2, further comprising:
an antenna terminal; and
a switch integrated circuit (IC) comprising a switch configured to selectively connect a destination for the antenna terminal,
wherein the reception-system component is the switch IC.

4. The high frequency module according to claim 1, wherein the third component is a reception filter for a reception signal.

5. The high frequency module according to claim 1,
wherein the third component comprises a ground terminal that is connected to ground,
wherein the third component comprises a through-hole via, and
wherein the via connects the ground terminal to the ground electrode.

6. The high frequency module according to claim 1, wherein the third component is a matching circuit that is in a different path than a path through which the first transmission signal passes and than a path through which the second transmission signal passes.

7. The high frequency module according to claim 6, further comprising:
a ground terminal that is connected to a first end of the matching circuit and to ground, the ground terminal being on the second main surface of the mounting substrate,
wherein the ground terminal is between the first component and the second component in the plan view of the mounting substrate.

8. The high frequency module according to claim 1, wherein a top surface of the third component is connected to the ground electrode.

9. The high frequency module according to claim 1,
wherein the first component, the second component, and the third component are arranged along a short side of the first component in the plan view of the mounting substrate, and
wherein the third component is arranged such that a long side of the third component intersects a direction along the short side of the first component.

10. The high frequency module according to claim 1, wherein the first component, the second component, and the third component are arranged along a short side of the second component in the plan view of the mounting substrate.

11. The high frequency module according to claim 1,
wherein the first component comprises an input terminal to which the first transmission signal is input, and
wherein, among sides of the first component that intersect a direction along which the first component, the second component, and the third component are arranged, the input terminal of the first component is closest to a short side that is closest to the third component.

12. The high frequency module according to claim 1,
wherein the second component comprises an input terminal to which the second transmission signal is input, and
wherein among sides of the second component that intersect a direction along which the first component, the second component, and the third component are arranged, the input terminal of the second component is arranged closest to a short side that is closest to the third component.

13. The high frequency module according to claim 1,
wherein the frequency band of the first transmission signal is a frequency band based on 4G standards, and
wherein the frequency band of the second transmission signal is a frequency band based on 5G standards.

14. The high frequency module according to claim 13, wherein a combination of the frequency band of the first transmission signal and the frequency band of the second transmission signal is a combination of Band 1 and n40, a combination of Band 3 and n40, a combination of Band 1 and n41, a combination of Band 3 and n41, a combination of Band 39 and n41, a combination of Band 66 and n41, or a combination of Band 25 and n41.

15. A high frequency module comprising:
a mounting substrate that has a first main surface and a second main surface that are opposite to each other;
a plurality of components that are on the first main surface;
a resin layer that covers at least part of the plurality of components; and
a ground electrode that covers at least part of the resin layer,
wherein the plurality of components comprises a first component, a second component, and a third component,
wherein the first component is a first transmission filter or a first transmission power amplifier for a first transmission signal,
wherein the second component is a second transmission filter or a second transmission power amplifier for a second transmission signal of a frequency band different from a frequency band of the first transmission signal,
wherein a top surface of the first component and a top surface of the second component are connected to the ground electrode,
wherein the third component is configured not to perform a simultaneous transmission operation together with the first component and the second component,
wherein the third component is between the first component and the second component in a plan view from a thickness direction of the mounting substrate, and
wherein a combination of the frequency band of the first transmission signal and the frequency band of the second transmission signal is a combination of Band 1 based on 4G standards and n40 based on 5G standards, a combination of Band 3 based on the 4G standards and n40 based on the 5G standards, a combination of Band 1 based on the 4G standards and n41 based on the 5G standards, a combination of Band 3 based on the 4G standards and n41 based on the 5G standards, a combination of Band 39 based on the 4G standards and n41 based on the 5G standards, a combination of Band 66 based on the 4G standards and n41 based on the 5G standards, or a combination of Band 25 based on the 4G standards and n41 based on the 5G standards.

16. A communication apparatus comprising:
the frequency module according to claim 1; and
a signal processing circuit configured to process the first transmission signal and the second transmission signal that pass through the high frequency module.

17. A communication apparatus comprising:
the frequency module according to claim 2; and
a signal processing circuit configured to process the first transmission signal and the second transmission signal that pass through the high frequency module.

18. A communication apparatus comprising:
the frequency module according to claim 15; and
a signal processing circuit configured to process the first transmission signal and the second transmission signal that pass through the high frequency module.
